(19) United States
(12) Patent Application Publication
(10) Pub. No.: US 2025/0143104 A1
(43) Pub. Date: May 1, 2025

(54) DISPLAY DEVICE, AND HEAD MOUNTED DISPLAY DEVICE INCLUDING THE SAME

(71) Applicant: Samsung Display Co., LTD., Yongin-si (KR)

(72) Inventors: Jin Seon KWAK, Yongin-si (KR); Kyung Bae KIM, Yongin-si (KR); Kyeong Min PARK, Yongin-si (KR); Yong Hee LEE, Yongin-si (KR)

(21) Appl. No.: 18/798,636

(22) Filed: Aug. 8, 2024

(30) Foreign Application Priority Data
Oct. 30, 2023 (KR) 10-2023-0146878

(51) Int. Cl. H10K 59/127; G02B 27/01; H10K 59/121; H10K 59/131

(52) U.S. Cl. CPC H10K 59/1275; G02B 27/0172; H10K 59/1213; H10K 59/131; G02B 2027/0178

(57) ABSTRACT

A display device and head mounted display device including the same are provided. The display device includes a first single-crystal semiconductor substrate, first transistors above the first single-crystal semiconductor substrate, and a second single-crystal semiconductor substrate above the first single-crystal semiconductor substrate, having an area that is greater than an area of the first single-crystal semiconductor substrate in plan view, and including a display area in which light-emitting elements are located, and a non-display area around the display area in plan view, wherein the second single-crystal semiconductor substrate defines first through holes defined in the display area and having a first conductive via electrically connected to the light-emitting element, second through holes defined in the display area and having a second conductive via electrically connected to the first transistor, and third through holes defined in the non-display area and having a third conductive via therein.

### CROSS-REFERENCE TO RELATED APPLICATION

The present application claims priority to, and the benefit of, Korean Patent Application No. 10-2023-0146878, filed on Oct. 30, 2023, in the Korean Intellectual Property Office, the entire disclosure of which is incorporated herein by reference.

### BACKGROUND

### 1. Field

The present disclosure relates to a display device, and a head mounted display device including the same.

### 2. Description of the Related Art

A head mounted display device (HMD) is an image display device that is worn on a user's head in the form of glasses or a helmet to form a focus at a close distance in front of the user's eyes. The head mounted display device may implement virtual reality (VR) or augmented reality (AR).

The head mounted display device magnifies an image displayed on a small display device by using a plurality of lenses, and displays the magnified image.

Therefore, the display device applied to the head mounted display device may suitably provide high-resolution images, for example, images with a resolution of 3000 PPI (Pixels Per Inch) or higher. To this end, an organic light-emitting diode on silicon (OLEDoS), which is a high-resolution small organic light-emitting display device, is used as the display device applied to the head mounted display device. The OLEDoS is an image display device in which an organic light-emitting diode (OLED) is located on a semiconductor wafer substrate on which a complementary metal oxide semiconductor (CMOS) is located.

### SUMMARY

Aspects of the present disclosure provide a micro-display device including a plurality of different single-crystal semiconductor substrates, and a head mounted display device including the same.

Aspects of the present disclosure also provide a micro-display device having circuit elements dividedly located on different single-crystal semiconductor substrates, and a head mounted display device including the same.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to one or more embodiments of the disclosure, a display device includes a first single-crystal semiconductor substrate, first transistors above the first single-crystal semiconductor substrate, and a second single-crystal semiconductor substrate above the first single-crystal semiconductor substrate, having an area that is greater than an area of the first single-crystal semiconductor substrate in plan view, and including a display area in which light-emitting elements are located, and a non-display area around the display area in plan view, wherein the second single-crystal semiconductor substrate defines first through holes defined in the display area and having a first conductive via electrically connected to the light-emitting element, second through holes defined in the display area and having a second conductive via electrically connected to the first transistor, and third through holes defined in the non-display area and having a third conductive via therein.

The display device may further include a pixel circuit portion above the first single-crystal semiconductor substrate, and including some of the first transistors, a signal driver above the first single-crystal semiconductor substrate, and including others of the first transistors, and second transistors above the second single-crystal semiconductor substrate.

One of the light-emitting elements may be electrically connected to one of the first transistor of the pixel circuit portion through the first conductive via, wherein one of the second transistors is electrically connected to the one of the first transistors of the pixel circuit portion through the second conductive via.

The display device may further include signal lines located across the display area and the non-display area on the second single-crystal semiconductor substrate, and connected to the third conductive via in the non-display area.

The signal lines may be electrically connected to the second transistors in the display area, and may be electrically connected to the signal driver through the third conductive via.

A minimum line width of the first transistors may be less than a minimum line width of the second transistors.

A number of the first through holes may be equal to a number of the second through holes.

A number of the first through holes and a second through holes may be greater than a number of the third through holes.

The first through holes may overlap the light-emitting elements in a thickness direction.

Some of the first through holes or the second through holes might not overlap the first single-crystal semiconductor substrate.

The third through holes might not overlap the first single-crystal semiconductor substrate.

The display device may further include a connection wiring layer including connection lines electrically connected to one of the first conductive via, the second conductive via, or the third conductive via between the first single-crystal semiconductor substrate and a light-emitting element layer including the light-emitting elements.

The connection wiring layer may be between the first single-crystal semiconductor substrate and the second single-crystal semiconductor substrate.

The connection wiring layer may be between the second single-crystal semiconductor substrate and the light-emitting element layer.

The display device may further include a passivation layer surrounding the first single-crystal semiconductor substrate, and partially in contact with the second single-crystal semiconductor substrate.

According to one or more embodiments of the disclosure, a display device

Includes a first single-crystal semiconductor substrate first transistors above the first single-crystal semiconductor substrate, a second single-crystal semiconductor substrate above the first single-crystal semiconductor substrate, second transistors above the second single-crystal semiconductor substrate, at least one signal line electrically connected to the second transistor, a light-emitting element layer above the second single-crystal semiconductor substrate, and including light-emitting elements, and a connection wiring layer between the light-emitting element layer and the first single-crystal semiconductor substrate, and including a first connection line connected to a first conductive via in a first through hole penetrating the second single-crystal semiconductor substrate, and electrically connected to one of the second transistors and one of the first transistors, and a second connection line connected to a second conductive via in a second through hole penetrating the second single-crystal semiconductor substrate, and electrically connected to any one of the signal lines.

The connection wiring layer may further include a third connection line connected to a third conductive via in a third through hole penetrating the second single-crystal semiconductor substrate, wherein the third connection line is electrically connected to one of the light-emitting elements and one of the first transistors.

The signal line may be electrically connected one of the first transistors above the first single-crystal semiconductor substrate through the second conductive via and the second connection line.

An area of the first single-crystal semiconductor substrate in plan view may be less than an area of the second single-crystal semiconductor substrate in plan view.

According to one or more embodiments of the disclosure, a head mounted display device includes a frame mounted on a user's body and corresponding to left and right eyes, display devices in the frame, and lenses above the display devices, wherein the display device includes a first single-crystal semiconductor substrate, first transistors above the first single-crystal semiconductor substrate, a second single-crystal semiconductor substrate above the first single-crystal semiconductor substrate, second transistors above the second single-crystal semiconductor, at least one signal line electrically connected to the second transistor, a light-emitting element layer above the second single-crystal semiconductor substrate, and including light-emitting elements, and a connection wiring layer between the light-emitting element layer and the first single-crystal semiconductor substrate, and including a first connection line connected to a first conductive via in a first through hole penetrating the second single-crystal semiconductor substrate, and electrically connected to the second transistor and the first transistor, and a second connection line connected to a second conductive via in a second through hole penetrating the second single-crystal semiconductor substrate, and electrically connected to any one of the signal lines.

The display device according to one or more embodiments may include two different single-crystal semiconductor substrates, and the manufacturing process of the single-crystal semiconductor substrate located on the lower portion is capable of producing a large quantity per unit wafer substrate, thereby improving manufacturing yield.

In addition, in the display device according to one or more embodiments, circuit elements constituting a pixel circuit may be dividedly located on two different single-crystal semiconductor substrates, thereby alleviating high integration density on the single-crystal semiconductor substrate with a small area and reducing parasitic capacitance that may be formed between adjacent circuit elements.

However, aspects according to the embodiments of the present disclosure are not limited to the above and various other aspects are incorporated herein.

### BRIEF DESCRIPTION OF THE DRAWINGS

The above and other aspects of the present disclosure will become more apparent by describing in detail embodiments thereof with reference to the attached drawings, in which:

FIG. 1 is an exploded perspective view of a display device according to one or more embodiments;

FIG. 2 is a plan view illustrating an example of the driving part shown in FIG. 1;

FIG. 3 is a plan view illustrating an example of the display part shown in FIG. 1;

FIG. 4 is a block diagram illustrating a display device according to one or more embodiments;

FIG. 5 is an equivalent circuit diagram of one pixel according to one or more embodiments;

FIG. 6 is an enlarged plan view of a portion of a driving part in a display device according to one or more embodiments;

FIG. 7 is an enlarged plan view illustrating a portion of a display part in a display device according to one or more embodiments;

FIG. 8 is a diagram schematically illustrating a connection between a driving part and a display part in a display device according to one or more embodiments;

FIG. 9 is a schematic cross-sectional view of a display device according to one or more embodiments;

FIG. 10 is a schematic cross-sectional view of a driving part according to one or more embodiments;

FIG. 11 is a plan view illustrating the layout of pixels located in a display area of a display part according to one or more embodiments;

FIG. 12 is a cross-sectional view showing a portion of a display area and a portion of a non-display area in a display part according to one or more embodiments;

FIGS. 13 and 14 are plan views illustrating the layout of a display area of a display part according to one or more other embodiments;

FIG. 15 is an equivalent circuit diagram of a sub-pixel of a display device according to one or more other embodiments;

FIG. 16 is a schematic cross-sectional view of a display device according to one or more other embodiments;

FIG. 17 is a perspective view illustrating a head mounted display device according to one or more embodiments;

FIG. 18 is an exploded perspective view showing an example of the head mounted display device of FIG. 17; and

FIG. 19 is a perspective view illustrating a head mounted display device according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing one or more embodiments corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

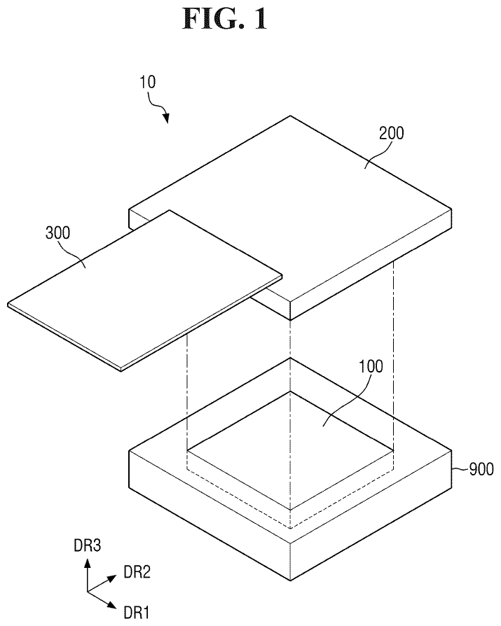

FIG. 1 is an exploded perspective view of a display device according to one or more embodiments.

Referring to FIG. 1, a display device 10 according to one or more embodiments is a device for displaying a moving image or a still image. The display device 10 according to one or more embodiments may be applied to portable electronic devices such as a mobile phone, a smartphone, a tablet personal computer, a mobile communication terminal, an electronic organizer, an electronic book, a portable multimedia player (PMP), a navigation system, an ultra-mobile PC (UMPC) or the like. For example, the display device 10 may be applied as a display part of a television, a laptop, a monitor, a billboard, or an Internet-of-Things (IoT) device. Alternatively, the display device 10 may be applied to a smart watch, a watch phone, a head mounted display device (HMD) for implementing virtual reality and augmented reality, and the like.

The display device 10 according to one or more embodiments may include a driving part 100, a display part 200, and a circuit board 300. The display device 10 may further include a passivation layer 900 located around the driving part 100 (e.g., in plan view).

The driving part 100 may have a planar shape similar to a quadrilateral shape. For example, the driving part 100 may have a planar shape similar to a square, having one side of the first direction DR1, and the other side of a second direction DR2 crossing a first direction DR1. In the driving part 100, a corner where one side in the first direction DR1 and the other side in the second direction DR2 meet may be right-angled or rounded with a curvature (e.g., predetermined curvature). The planar shape of the driving part 100 is not limited to a rectangular shape, and may be a shape similar to another polygonal shape, a circular shape, or an elliptical shape. The planar shape of the display device 10 may conform to the planar shape of the driving part 100, but is not limited thereto.

The display part 200 may be located on the driving part 100. In FIG. 1, the display part 200 and the driving part 100 are illustrated as being spaced apart from each other, but this is only an example where they are separated for the purpose of illustrating the driving part 100. In the display device 10, the driving part 100 and the display part 200 may be bonded to each other. The display part 200 may have a shape or profile that is substantially similar to that of the driving part 100. For example, the driving part 100 may have a planar shape similar to a square, having one side of the first direction DR1, and the other side of the second direction DR2 crossing the first direction DR1. The planar shape of the display part 200 is not limited to a rectangular shape, and may be a shape similar to another polygonal shape, a circular shape, or an elliptical shape.

According to one or more embodiments, in the display device 10, the area of the display part 200 in plan view may be greater than the area of the driving part 100 in plan view. The display device 10 may include the driving part 100 and the display part 200 having different substrates, and they may have different areas. Elements formed in the driving part 100 and elements formed in the display part 200 may be different, and these elements may be formed individually on different substrates. The display device 10 may be manufactured by forming multiple elements with different sizes, line widths, and manufacturing processes on different substrates and then bonding them. This display device 10 may have aspects in which product performance and manufacturing yield can be improved. A description thereof will be given later with reference to other drawings.

The circuit board 300 may be electrically connected to a plurality of pads in a pad area of the display part 200 by using a conductive adhesive, such as an anisotropic conductive film. The circuit board 300 may be a flexible printed circuit board with a flexible material, or a flexible film. Although the circuit board 300 is illustrated in FIG. 1 as being unfolded, the circuit board 300 may be bent. In this case, one end of the circuit board 300 may be located on the bottom surface of the driving part 100. The other end of the circuit board 300 may be connected to the plurality of pads in the pad area of the display part 200 by using the conductive adhesive.

In one or more embodiments, the display device 10 may further include a heat dissipation layer overlapping the driving part 100 and the display part 200 in a third direction DR3. The heat dissipation layer may be located on the bottom surface of the driving part 100, and may dissipate heat generated from the driving part 100 and the display part 200. The heat dissipation layer may include a metal layer, such as graphite, silver (Ag), copper (Cu), or aluminum (Al) having high thermal conductivity.

The passivation layer 900 may be located on the bottom surface of the display part 200 while surrounding the driving part 100. The passivation layer 900 may reduce a step due to the difference in the area between the driving part 100 and the display part 200, and may also protect the driving part 100 and the display part 200.

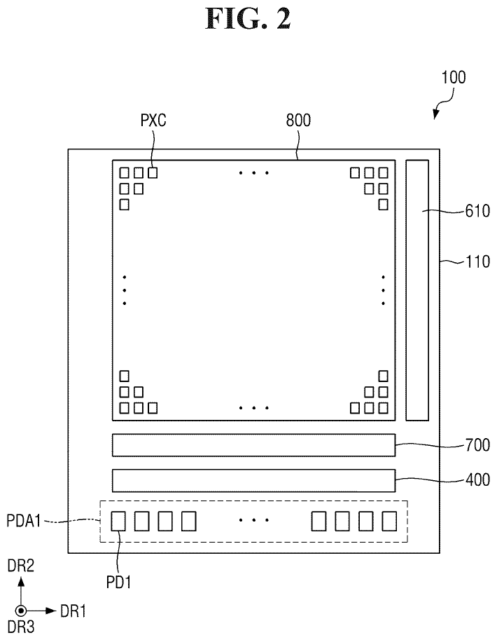

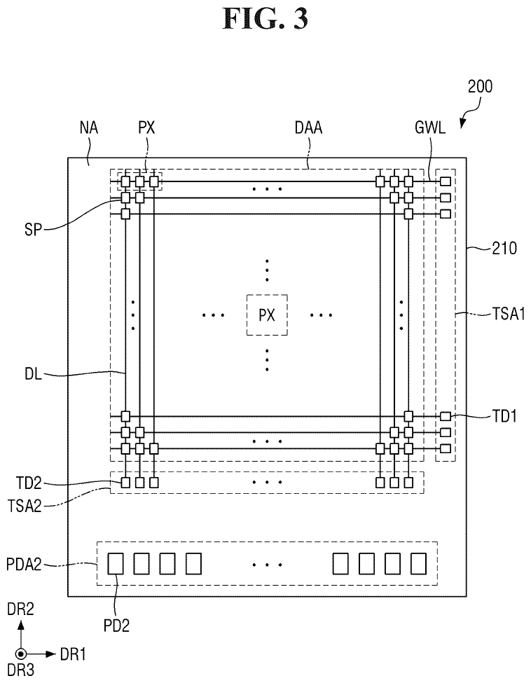

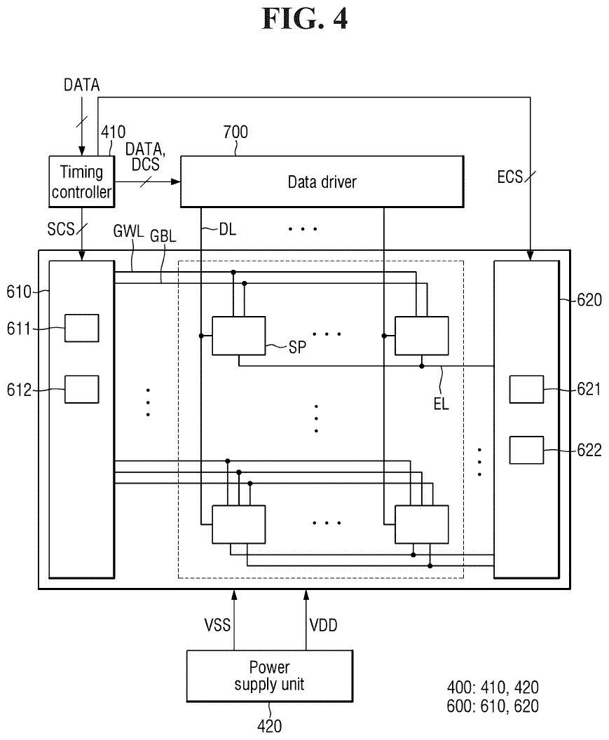

FIG. 2 is a plan view illustrating an example of the driving part shown in FIG. 1. FIG. 3 is a plan view illustrating an example of the display part shown in FIG. 1. FIG. 4 is a block diagram illustrating a display device according to one or more embodiments.

Referring to FIGS. 2 to 4, the driving part 100 of the display device 10 may include driving circuit elements of the display device 10. The driving part 100 may include a first single-crystal semiconductor substrate 110, and a driving circuit portion 400, a gate driver 600, a data driver 700, and a pixel circuit portion 800 formed on the first single-crystal semiconductor substrate 110.

The first single-crystal semiconductor substrate 110 may be a silicon substrate, a germanium substrate, or a silicon-germanium substrate. Transistors of the driving circuit elements may be formed on the first single-crystal semiconductor substrate 110. The plurality of transistors may be electrically connected to each other to form the driving circuit portion 400, the gate driver 600, the data driver 700, and the pixel circuit portion 800.

It is illustrated in the drawing that the pixel circuit portion 800 is located, generally, at the center of the driving part 100, the gate driver 600 is located on the right thereof, and the data driver 700 and the driving circuit portion 400 are located below the pixel circuit portion 800. However, the present disclosure is not limited thereto. In the driving part 100, the positions of the driving circuit portion 400, the gate driver 600, the data driver 700, and the pixel circuit portion 800 may be changed in various ways according to the design structure of multiple circuit elements formed on the first single-crystal semiconductor substrate 110.

The driving circuit portion 400 may include a timing control circuit 410 and a power supply circuit 420. In addition, the driving circuit portion 400 may further include various circuits involved in driving the display device 10, such as a gamma circuit and a logic circuit. The driving circuit portion 400 may include the plurality of transistors formed on the first single-crystal semiconductor substrate 110. The transistors may be formed through a semiconductor process. For example, the plurality of transistors may be formed as complementary metal oxide semiconductor (CMOS) transistors.

The timing control circuit 410 may receive digital video data and timing signals inputted from the outside. The timing control circuit 410 may generate a scan timing control signal SCS, an emission timing control signal ECS, and a data timing control signal DCS for controlling the display part 200 according to the timing signals. The timing control circuit 410 may output the scan timing control signal SCS to a scan driver 610 of the gate driver 600, and may output the emission timing control signal ECS to an emission driver 620 of the gate driver 600. The timing control circuit 410 may output the digital video data and the data timing control signal DCS to the data driver 700.

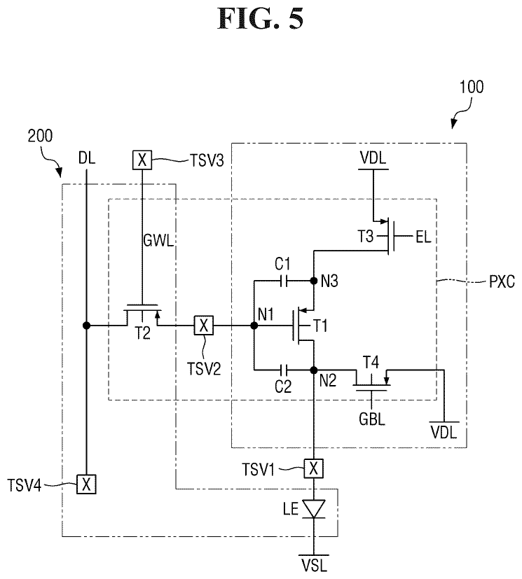

The power supply circuit 420 may generate a plurality of panel driving voltages according to a power voltage from the outside. For example, the power supply circuit 420 may generate a first driving voltage VSS and a second driving voltage VDD to supply them to the pixel circuit portion 800. Description of the first driving voltage VSS and the second driving voltage VDD will be provided later with reference to FIG. 5.

The scan timing control signal SCS, the emission timing control signal ECS, digital video data DATA, and the data timing control signal DCS of the timing control circuit 410 may be supplied to the pixel circuit portion 800. The first driving voltage VSS and the second driving voltage VDD of the power supply circuit 420 may also be supplied to the pixel circuit portion 800. The driving part 100 may be bonded to the bottom surface of the display part 200, and the driving circuit portion 400 of the driving part 100 may be electrically connected to the display part 200.

The gate driver 600 may include the scan driver 610 and the emission driver 620. The scan driver 610 includes a plurality of scan transistors formed on the first single-crystal semiconductor substrate 110, and the emission driver 620 includes a plurality of emission transistors formed on the first single-crystal semiconductor substrate 110. The plurality of scan transistors and the plurality of emission transistors may be formed through a semiconductor process. For example, the plurality of scan transistors and the plurality of emission transistors may be formed as CMOS transistors.

The scan driver 610 may include a first scan signal output part 611 and a second scan signal output part 612. Each of the first scan signal output part 611 and the second scan signal output part 612 may receive a scan timing control signal SCS from the timing control circuit 410. The first scan signal output part 611 may generate write scan signals according to the scan timing control signal SCS of the timing control circuit 410, and may output them sequentially to first scan lines GWL. The second scan signal output part 612 may generate bias scan signals according to the scan timing control signal SCS, and may output them sequentially to second scan lines GBL.

The emission driver 620 may receive an emission timing control signal ECS from the timing control circuit 410. The emission driver 620 may generate emission control signals in response to the emission timing control signal ECS, and may sequentially output them to emission control lines EL.

The data driver 700 includes a plurality of data transistors formed on the first single-crystal semiconductor substrate 110. The plurality of data transistors may be formed through a semiconductor process. For example, the plurality of data transistors may be formed as CMOS transistors. The data driver 700 may receive the digital video data DATA and the data timing control signal DCS from the timing control circuit 410. The data driver 700 converts the digital video data DATA into analog data voltages according to the data timing control signal DCS and outputs the analog data voltages to the data lines DL. In this case, sub-pixels SP are selected by the write scan signal of the scan driver 610, and the data voltages may be supplied to the selected sub-pixels SP. The gate driver 600 and the data driver 700 may be any one of the signal drivers included in the driving part 100.

A first pad area PDA1 may include a plurality of first pads PD1 arranged in the first direction DR1. The plurality of first pads PD1 may be electrically connected to a plurality of second pads PD2 of the display part 200, and may be electrically connected to the circuit board 300 through these second pads PD2. The first pads PD1 may transmit an electrical signal applied from the circuit board 300 to the driving circuit portion 400, the gate driver 600, the data driver 700, and the pixel circuit portion 800.

The pixel circuit portion 800 includes a plurality of pixel transistors formed on the first single-crystal semiconductor substrate 110. The plurality of pixel transistors may be formed through a semiconductor process. For example, the plurality of pixel transistors may be formed as CMOS transistors. The pixel circuit portion 800 may be any one of the driving circuits included in the driving part 100.

A plurality of pixel circuits PXC, the plurality of second scan lines GBL (see FIG. 4), and the plurality of emission control lines EL (see FIG. 4) may be located in the pixel circuit portion 800. The plurality of pixel circuits PXC may be arranged to be spaced apart from each other in the first direction DR1 and the second direction DR2. The plurality of second scan lines GBL and the emission control lines EL may extend in the first direction DR1, and may be arranged to be spaced apart from each other in the second direction DR2. The second scan line GBL and the emission control line EL may be any one of the signal lines included in the driving part 100 of the display device 10.

The plurality of data lines DL and the plurality of first scan lines GWL may be located in the display part 200. The plurality of data lines DL may extend in the second direction DR2, and may be arranged to be spaced apart from each other in the first direction DR1. The plurality of first scan lines GWL may extend in the first direction DR1, and may be arranged to be spaced apart from each other in the second direction DR2. The first scan line GWL and the data line DL may be any one of the signal lines included in the display part 200 of the display device 10.

In the display device 10 according to one or more embodiments, some of transistors T1, T2, T3, and T4 (see FIG. 5) included in the pixel circuit PXC connected to the sub-pixel SP, and the plurality of wires respectively connected thereto, may be located on different single-crystal semiconductor substrates. The display device 10 may include the driving part 100 and the display part 200, each including a different single-crystal semiconductor substrate, and the transistors of the pixel circuit PXC and the plurality of wires may be dividedly located in the driving part 100 and the display part 200.

For example, among the plurality of wires, the plurality of second scan lines GBL (see FIG. 4) and the plurality of emission control lines EL (see FIG. 4) may be located in the driving part 100. The plurality of data lines DL and the plurality of first scan lines GWL may be located in the display part 200. Among the circuit elements included in the pixel circuit PXC, the circuit elements connected to the data line DL and the first scan line GWL may be located in the display part 200, and other circuit elements may be located in the pixel circuit portion 800 of the driving part 100.

Because some wires and some circuit elements of the pixel circuit PXC are dividedly located on different single-crystal semiconductor substrates, the display device 10 may solve the difficulty of layout design due to high integration density in a small area, and may reduce or prevent a parasitic capacitance between adjacent elements. A more detailed description thereof will be given later with reference to other drawings.

A plurality of scan lines SL may include the plurality of first scan lines GWL and the plurality of second scan lines GBL. The plurality of scan lines SL, the plurality of emission control lines EL, and the plurality of data lines DL may be electrically connected to the plurality of pixel transistors, and the pixel circuit portion 800 may be electrically connected to the sub-pixels SP of the display part 200 to transmit electrical signals suitable for light emission of light-emitting elements.

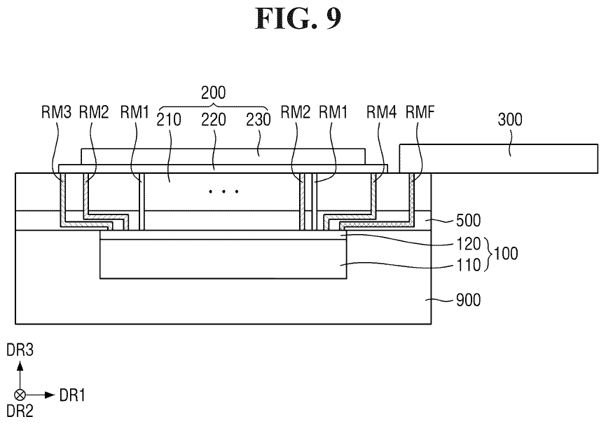

The display part 200 may include a display area DAA in which light-emitting elements that emit light are located to display an image, and a non-display area NA located around the display area DAA. The display part 200 may include a second single-crystal semiconductor substrate 210, a sub-pixel circuit portion 220 (see FIG. 9) located on the second single-crystal semiconductor substrate 210, and a display element layer 230 (see FIG. 9).

The second single-crystal semiconductor substrate 210 may be a silicon substrate, a germanium substrate, or a silicon-germanium substrate. Transistor elements may not be formed on the second single-crystal semiconductor substrate 210. However, the present disclosure is not limited thereto. In one or more other embodiments, the second single-crystal semiconductor substrate 210 may also include circuit elements suitable for driving the display device 10.

The plurality of first scan lines GWL extending in the first direction DR1 and arranged in the second direction DR2, and the plurality of data lines DL extending in the second direction DR2 and arranged in the first direction DR1, may be located in the display area DAA. The first scan lines GWL and the data lines DL may be connected to the plurality of sub-pixels SP of the display area DAA. In addition, the first scan lines GWL and the data lines DL may be connected to the gate driver 600 and the data driver 700 of the driving part 100.

The plurality of sub-pixels SP including light-emitting elements may be arranged in the display area DAA. The plurality of sub-pixels SP (e.g., three sub-pixels SP) may constitute one pixel PX to display a color. However, the present disclosure is not limited thereto, and one pixel PX may include three or more sub-pixels SP. The plurality of sub-pixels SP may be arranged in a matrix form in the first direction DR1 and the second direction DR2. Each of the plurality of sub-pixels SP may be electrically connected to the pixel circuit portion 800 of the driving part 100, and to the sub-pixel circuit portion 220 (see FIG. 9) of the display part 200. Each of the sub-pixels SP includes light-emitting elements, and each light-emitting element may emit light according to an electrical signal applied from the pixel circuit portion 800. Some of the sub-pixels SP located in the display area DAA of the display part 200 may overlap the pixel circuit portion 800 of the driving part 100 in the thickness direction. However, the sub-pixels SP and the pixel circuit portion 800 are located on the separate single-crystal semiconductor substrates 110 and 210, and may be electrically connected to each other through a connection wiring layer 500 (see FIG. 9) located between them.

Each of the plurality of sub-pixels SP may be connected to the first scan line GWL and the data line DL, and to the second scan line GBL and the emission control line EL of the pixel circuit portion 800. Each of the plurality of sub-pixels SP may receive the data voltage of the data line DL according to the write scan signal of the first scan line GWL, and may emit light from a light-emitting element thereof according to the data voltage.

The non-display area NA may surround the display area DAA (e.g., in plan view). The non-display area NA may be an area where no pixels PX are located, and therefore no light is emitted therefrom. A plurality of through hole areas TSA1 and TSA2 and a second pad area PDA2 may be located in the non-display area NA.

The second pad area PDA2 may include the plurality of second pads PD2 arranged in the first direction DR1. The plurality of second pads PD2 may be electrically connected to the plurality of first pads PD1 of the driving part 100, and the circuit board 300 may be attached thereon. The second pads PD2 may be electrically connected to the circuit board 300, and may serve to transmit the electrical signal applied from the circuit board 300 to the driving part 100.

Each of the plurality of through hole areas TSA1 and TSA2 may be located toward one side of the display area DAA. For example, a first through hole area TSA1 may be located toward the right side of the display area DAA, which is one side in the first direction DR1. A second through hole area TSA2 may be located toward the lower side of the display area DAA, which is the other side in the second direction DR2. The second through hole area TSA2 may be located between the display area DAA and the second pad area PDA2. However, the positions of the through hole areas TSA1 and TSA2 are not limited thereto, and may be varied depending on the design of the display part 200 and the driving part 100.

The plurality of first scan lines GWL may extend from the first through hole area TSA1 in the first direction DR1 to be located in the display area DAA. The first scan lines GWL may be connected to first terminals TD1 located in the first through hole area TSA1. The plurality of data lines DL may extend from the second through hole area TSA2 in the second direction DR2 to be located in the display area DAA. The data lines DL may be connected to second terminals TD2 located in the second through hole area TSA2.

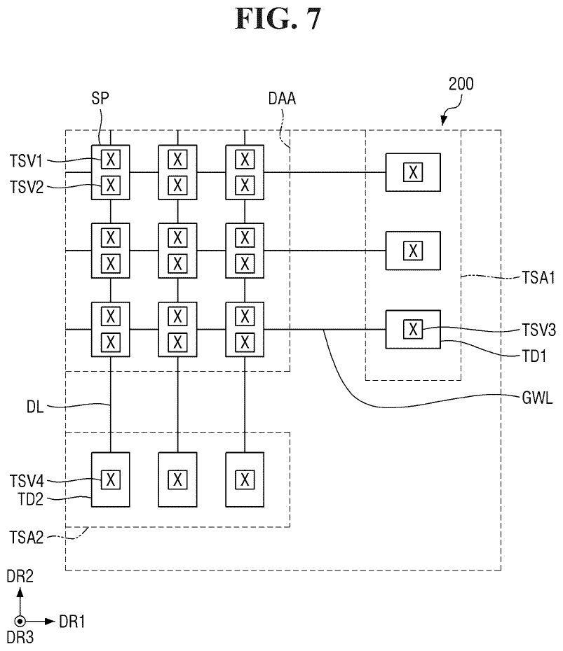

In the display device 10, different elements, wires, circuits, and the like located in the driving part 100 and the display part 200 may be connected to each other via through holes penetrating the second single-crystal semiconductor substrate 210 of the display part 200. For example, the first terminal TD1 may be connected to the gate driver 600 of the driving part 100 through a through hole TSV3 (see FIG. 7) formed in the first through hole area TSA1. The second terminal TD2 may be connected to the data driver 700 of the driving part 100 through a through hole TSV4 (see FIG. 7) formed in the second through hole area TSA2. In addition, in one or more embodiments, the circuit elements of the sub-pixel circuit portion 220 located in the display area DAA, and the light-emitting element of the sub-pixel SP may also be electrically connected to the pixel circuit portion 800 of the driving part 100 through a plurality of through holes formed in the display area DAA. In the display device 10, the elements for light emission of the light-emitting elements may be dividedly located in the driving part 100 and the display part 200. The driving part 100 may have a large number of circuit elements arranged with high integration density, and power consumption may be reduced due to miniaturization of the element. In addition, because the elements of the pixel circuit PXC for light emission of the sub-pixel SP are also dividedly located in the driving part 100 and the display part 200, concentration of the circuit elements in the driving part 100 may be reduced or prevented, thereby solving design difficulties associated with high integration density. In addition, because the circuit elements are not concentrated in the driving part 100 with a relatively small area, the parasitic capacitance between adjacent elements may be reduced.

FIG. 5 is an equivalent circuit diagram of one pixel according to one or more embodiments.

Referring to FIG. 5, the pixel circuit PXC of the sub-pixel SP may include the plurality of transistors T1, T2, T3, and T4 and a plurality of capacitors C1 and C2. The pixel circuit PXC may be connected to a light-emitting element LE, the first scan line GWL, the second scan line GBL, the emission control line EL, and the data line DL. Further, the pixel circuit PXC may be connected to a first driving voltage line VSL to which the first driving voltage VSS corresponding to a low potential voltage is applied, and a second driving voltage line VDL to which the second driving voltage VDD corresponding to a high potential voltage is applied. The first driving voltage line VSL may be a low potential voltage line and the second driving voltage line VDL may be a high potential voltage line.

The pixel circuit PXC of the sub-pixel SP includes the plurality of transistors T1, T2, T3, and T4 electrically connected to the light-emitting element LE, a first capacitor C1, and a second capacitor C2.

The light-emitting element LE may emit light in response to a driving current flowing in the channel of the first transistor T1. A light emission amount of the light-emitting element LE may be proportional to the driving current. The light-emitting element LE may be located between the first transistor T1 and the first driving voltage line VSL. The first electrode of the light-emitting element LE may be connected to the drain electrode of the first transistor T1, and the second electrode thereof may be connected to the first driving voltage line VSL. The first electrode of the light-emitting element LE may be an anode electrode, and the second electrode of the light-emitting element LE may be a cathode electrode. The light-emitting element LE may be an organic light-emitting diode including a first electrode, a second electrode, and an organic light-emitting layer located between the first electrode and the second electrode, but is not limited thereto. For example, the light-emitting element LE may be an inorganic light-emitting element including a first electrode, a second electrode, and an inorganic semiconductor located between the first electrode and the second electrode.

The first transistor T1 may be a driving transistor that controls a source-drain current (hereinafter referred to as a “driving current”) flowing between the source electrode and the drain electrode thereof according to a voltage applied to the gate electrode thereof. The first transistor T1 includes a gate electrode connected to the first node N1, a source electrode connected to the drain electrode of the third transistor T3, and a drain electrode connected to the second node N2.

The second transistor T2 may be located between the gate electrode of the first transistor T1 and the data line DL. The second transistor T2 is turned on by the write scan signal of the first scan line GWL to connect the gate electrode of the first transistor T1 to the data line DL. As a result, the data voltage of the data line DL may be applied to the gate electrode of the first transistor T1. The second transistor T2 includes a gate electrode connected to the first scan line GWL, a drain electrode connected to the data line DL, and a source electrode connected to the gate electrode of the first transistor T1.

The third transistor T3 may be located between the second driving voltage line VDL and the third node N3, which is the source electrode of the first transistor T1. The third transistor T3 is turned on by the emission control signal of the emission control line EL to connect the second driving voltage line VDL to the source electrode of the first transistor T1. Accordingly, the second driving voltage VDD of the second driving voltage line VDL may be applied to the source electrode of the first transistor T1. The third transistor T3 includes a gate electrode connected to the emission control line EL, a source electrode connected to the second driving voltage line VDL, and a drain electrode connected to the third node N3, which is the source electrode of the first transistor T1.

The fourth transistor T4 may be located between the second driving voltage line VDL and the second node N2, which is the drain electrode of the first transistor T1. The fourth transistor T4 is turned on by the bias scan signal of the second scan line GBL to connect the second node N2 to the second driving voltage line VDL. As a result, the second driving voltage VDD of the second driving voltage line VDL may be applied to the first electrode of the light-emitting element LE. However, the second driving voltage VDD applied through the fourth transistor T4 may be an initialization voltage for initializing the light-emitting element LE. The fourth transistor T4 includes a gate electrode connected to the second scan line GBL, a source electrode connected to the second driving voltage line VDL, and a drain electrode connected to the second node N2.

The first capacitor C1 is formed between the first node N1 and the third node N3. In other words, the first capacitor C1 may be formed between the source electrode and the gate electrode of the first transistor T1. The first capacitor C1 includes one electrode connected to the first node N1 and the other electrode connected to the third node N3. The second capacitor C2 is formed between the first node N1 and the second node N2. In other words, the second capacitor C2 may be formed between the gate electrode and the drain electrode of the first transistor T1. The second capacitor C2 includes one electrode connected to the first node N1 and the other electrode connected to the second node N2.

The first node N1 is a contact point for the gate electrode of the first transistor T1, the source electrode of the second transistor T2, the one electrode of the first capacitor C1, and the one electrode of the second capacitor C2. The second node N2 is a contact point for the drain electrode of the first transistor T1, the drain electrode of the fourth transistor T4, the other electrode of the second capacitor C2, and the first electrode of the light-emitting element LE. The third node N3 is a contact point for the source electrode of the first transistor T1, the other electrode of the first capacitor C1, and the drain electrode of the third transistor T3.

Each of the first to fourth transistors T1, T2, T3, and T4 may be a metal-oxide-semiconductor field effect transistor (MOSFET). For example, each of the first to fourth transistors T1, T2, T3, and T4 may be a P-type MOSFET, but is not limited thereto. Each of the first to fourth transistors T1, T2, T3, and T4 may be an N-type MOSFET. Alternatively, some of the first to fourth transistors T1, T2, T3, and T4 may be P-type MOSFETs, and each of the remaining transistors may be an N-type MOSFET.

Although FIG. 5 illustrates that the pixel circuit PXC of the sub-pixel SP includes four transistors T1, T2, T3, and T4 and two capacitors C1 and C2, it should be noted that the pixel circuit PXC is not limited to that shown in FIG. 5. For example, the number of the transistors and the number of the capacitors of the pixel circuit PXC of the sub-pixel SP are not limited to the example shown in FIG. 5.

According to one or more embodiments, in the display device 10, the first transistor T1, the third transistor T3, the fourth transistor T4, the first capacitor C1, and the second capacitor C2 of the pixel circuit PXC may be located in the driving part 100, and the second transistor T2 may be located in the display part 200. In addition, the light-emitting element LE of the sub-pixel SP may be located in the display part 200. The first transistor T1, the third transistor T3, the fourth transistor T4, the first capacitor C1, and the second capacitor C2 may be located in the pixel circuit portion 800 of the driving part 100 and formed on the first single-crystal semiconductor substrate 110. The second transistor T2 may be located in the display area DAA or the sub-pixel circuit portion 220 of the display part 200 and formed on the second single-crystal semiconductor substrate 210. The light-emitting element LE may be located in the display area DAA or the display element layer 230 of the display part 200.

The circuit elements and the light-emitting element LE formed on different single-crystal semiconductor substrates may be connected through the through holes TSV1, TSV2, TSV3, and TSV4. For example, the light-emitting element LE may be located in the display part 200, and may be electrically connected to the first transistor T1 of the driving part 100 through a first through hole TSV1. The second transistor T2 may be located in the display part 200, and may be electrically connected to the first transistor T1 of the driving part 100 through a second through hole TSV2.

The second scan line GBL, the emission control line EL, and the second driving voltage line VDL may be located in the driving part 100, and the first scan line GWL and the data line DL may be located in the display part 200. The first scan line GWL may be connected to the gate driver 600 of the driving part 100 through a third through hole TSV3 to receive the write scan signal. The data line DL may be connected to the data driver 700 of the driving part 100 through a fourth through hole TSV4 to receive the data signal.

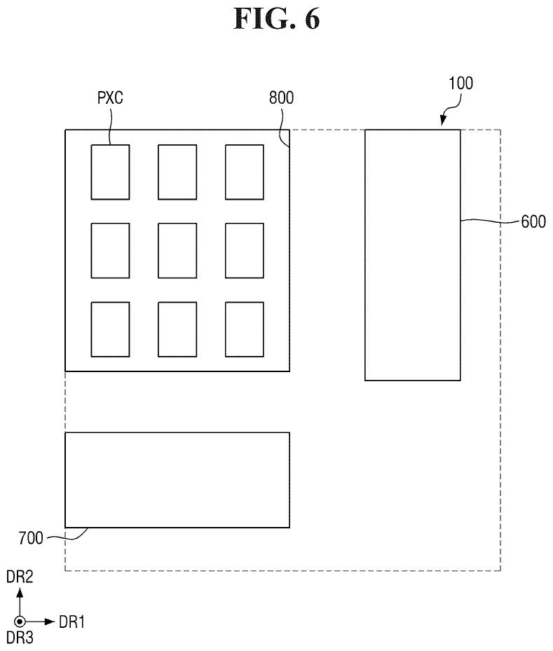

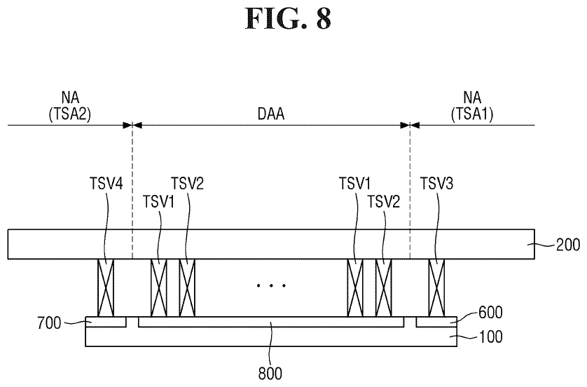

FIG. 6 is an enlarged plan view of a portion of a driving part in a display device according to one or more embodiments. FIG. 7 is an enlarged plan view illustrating a portion of a display part in a display device according to one or more embodiments. FIG. 8 is a diagram schematically illustrating a connection between a driving part and a display part in a display device according to one or more embodiments. For simplicity of description, FIG. 8 illustrates an approximate arrangement of the driving part 100, the display part 200, and the through holes TSV1, TSV2, TSV3, and TSV4 that serve as connection paths between the driving part 100 and the display part 200.

Referring to FIGS. 6 to 8, the display device 10 according to one or more embodiments may include the plurality of through holes TSV1, TSV2, TSV3, and TSV4 penetrating the second single-crystal semiconductor substrate 210 of the display part 200. The plurality of through holes TSV1, TSV2, TSV3, and TSV4 may be located in the display area DAA or the non-display area NA of the display part 200. The through holes located in the display area DAA of the display part 200 may form paths through which the light-emitting element LE and the transistor of the display part 200 (e.g., the second transistor T2 of the pixel circuit PXC) are connected to the pixel circuit portion 800. The through holes located in the non-display area NA of the display part 200 may form paths through which the first scan lines GWL and the data lines DL are connected to the gate driver 600 and the data driver 700, respectively. A routing line RM (see FIG. 9) to be described later may be located in each of the plurality of through holes TSV1, TSV2, TSV3, and TSV4, and the display part 200 may be electrically connected to the driving part 100 through the routing line RM.

For example, the display device 10 may include a plurality of first through holes TSV1 and a plurality of second through holes TSV2 overlapping the display area DAA of the display part 200. The routing line located in the first through hole TSV1 may be electrically connected to the pixel circuit portion 800 of the driving part 100, and to the light-emitting element LE of the display part 200. The routing line located in the second through hole TSV2 may be electrically connected to the pixel circuit portion 800 of the driving part 100, and to the second transistor T2 of the display part 200. The first through hole TSV1 may be a path for electrical connection between the pixel circuit PXC and the light-emitting element LE, and the second through hole TSV2 may be a path for electrical connection between some transistors of the pixel circuit PXC and other circuit elements.

According to one or more embodiments, the number of the plurality of first through holes TSV1 and second through holes TSV2 may be equal to the number of the plurality of pixel circuits PXC located in the pixel circuit portion 800, or may be equal to the number of the plurality of sub-pixels SP located in the display part 200. Because one pixel circuit PXC corresponds to one sub-pixel SP and one light-emitting element LE, one pixel circuit PXC may be electrically connected to the light-emitting element LE and the second transistor T2 located in the display part 200 through one first through hole TSV1 and one second through hole TSV2, respectively. However, in the display device 10, the display part 200 and the driving part 100 may have different areas in plan view. The display area DAA of the display part 200 and the pixel circuit portion 800 of the driving part 100 may also have different areas in plan view. Accordingly, the first through hole TSV1 and the second through hole TSV2 may not necessarily overlap the pixel circuit portion 800 and the pixel circuit PXC.

The display device 10 may include a plurality of third through holes TSV3 and a plurality of fourth through holes TSV4 overlapping the non-display area NA of the display part 200. The third through holes TSV3 may be located in the first through hole area TSA1 of the non-display area NA. The fourth through holes TSV4 may be located in the second through hole area TSA2. The plurality of terminals TD1 and TD2 may be located in the first through hole area TSA1 and the second through hole area TSA2, respectively, which may be areas where the plurality of third through holes TSV3 and the plurality of fourth through holes TSV4 are formed to overlap the terminals TD1 and TD2, respectively.

The first scan line GWL may be connected to the first terminal TD1 in the first through hole area TSA1. The first terminal TD1 may be electrically connected to the gate driver 600 of the driving part 100 through the routing line located in the third through hole TSV3. The data line DL may be connected to the second terminal TD2 in the second through hole area TSA2. The second terminal TD2 may be electrically connected to the data driver 700 of the driving part 100 through the routing line located in the fourth through hole TSV4. However, as described above, in the display device 10, the display part 200 and the driving part 100 may have different areas in plan view. The through hole areas TSA1 and TSA2 of the display part 200, and the gate driver 600 and the data driver 700 of the driving part 100, may have different areas in plan view. Accordingly, the third through hole TSV3 and the fourth through hole TSV4 may not necessarily overlap the gate driver 600 and the data driver 700, respectively.

According to one or more embodiments, the number of the third through holes TSV3 may be equal to the number of the first scan lines GWL. The number of the fourth through holes TSV4 may be equal to the number of the data lines DL. In one or more embodiments, the number of the third through holes TSV3 may be equal to the number of rows of the pixel circuits in an array of the pixel circuits PXC. The number of the fourth through holes TSV4 may be equal to the number of columns of the pixel circuits in the array of the pixel circuits PXC.

For example, one first scan line GWL may extend in the first direction DR1 to be connected to the plurality of sub-pixels SP belonging to the same row. The number of the first scan lines GWL may be equal to the number of pixel rows in the array of the plurality of sub-pixels SP. Because the plurality of sub-pixels SP correspond respectively to the pixel circuits PXC, the number of the first scan lines GWL may be equal to the number of rows of the pixel circuits in the array of the pixel circuits PXC, which may also be equal to the number of the third through holes TSV3.

One data line DL may extend in the second direction DR2 to be connected to the plurality of sub-pixels SP belonging to the same column. The number of the data lines DL may be equal to the number of pixel columns in the array of the plurality of sub-pixels SP. Because the plurality of sub-pixels SP correspond respectively to the pixel circuits PXC, the number of the data lines DL may be equal to the number of columns of the pixel circuits in the array of the pixel circuits PXC, which may also be equal to the number of the fourth through holes TSV4. Accordingly, in the display device 10, the numbers of each of the first through holes TSV1 and the second through holes TSV2 may be greater than the numbers of the third through holes TSV3 and the fourth through holes TSV4.

In the display device 10 according to one or more embodiments, the light-

emitting element LE located in the sub-pixel SP and the pixel circuit portion 800 may be located on different single-crystal semiconductor substrates. Some circuit elements (e.g., transistors) of the pixel circuit PXC in the pixel circuit portion 800 may also be located on a different single-crystal semiconductor substrate. In the display device 10, the pixel circuit portion 800, the light-emitting element LE, and the above-mentioned some circuit elements may be dividedly located on different single-crystal semiconductor substrates, thereby alleviating high integration density, and obtaining design freedom. In addition, some transistors of the pixel circuit PXC may be formed on a different substrate, thereby reducing the formation of parasitic capacitance between adjacent circuit elements.

FIG. 9 is a schematic cross-sectional view of a display device according to one or more embodiments.

Referring to FIG. 9, the display device 10 according to one or more embodiments may include the driving part 100 including the first single-crystal semiconductor substrate 110, and a driving circuit layer 120 located on the first single-crystal semiconductor substrate 110. The display device 10 may also include the display part 200 including the second single-crystal semiconductor substrate 210 and the sub-pixel circuit portion 220 and the display element layer 230 located on the second single-crystal semiconductor substrate 210. The display device 10 may include the two different single-crystal semiconductor substrates 110 and 210 overlapping each other in the third direction DR3, which is the thickness direction of the display device 10.

The driving part 100 may include circuit elements suitable for light emission of light-emitting elements included in the display element layer 230 of the display part 200. As described above, the driving circuit layer 120 of the driving part 100 may include the driving circuit portion 400, the gate driver 600, the data driver 700, the pixel circuit portion 800 and so forth, and the circuit elements constituting them, such as transistors and capacitors, may be formed of CMOS on the first single-crystal semiconductor substrate 110.

The display part 200 may include a plurality of light-emitting elements that emit light to display an image of the display device 10. The light-emitting elements may be electrically connected to the circuit elements formed in the driving part 100 to emit light. In addition, the display part 200 may include the sub-pixel circuit portion 220 in which a plurality of wires and some circuit elements constituting the pixel circuit PXC of the pixel circuit portion 800 are located. The sub-pixel circuit portion 220 may include some circuit elements (e.g., the second transistor T2 in FIG. 5) of the pixel circuit PXC. In addition, the sub-pixel circuit portion 220 may include the first scan line GWL and the data line DL located in the non-display area NA of the display part 200, and may include the plurality of terminals TD1 and TD2 located in the through hole areas TSA1 and TSA2.

According to one or more embodiments, in the display device 10, in plan view, the area of the driving part 100 or the first single-crystal semiconductor substrate 110 may be less than the area of the display part 200 or the second single-crystal semiconductor substrate 210. A plurality of transistors formed in the driving part 100 may be formed through a semiconductor micro-process, and thus may have a relatively very small size or line width. The driving part 100 has aspects in which a large number of circuit elements may be located with a high degree of integration, and power consumption may be reduced due to the miniaturization of the elements.

In addition, because the driving part 100 includes only the circuit elements formed of CMOS on the first single-crystal semiconductor substrate 110, and does not include light-emitting elements, the driving part 100 may suitably secure a space for accommodating the elements formed by the micro-process therein. Even if the first single-crystal semiconductor substrate 110 has a smaller area than the second single-crystal semiconductor substrate 210, and a large number of driving parts 100 may be manufactured on a single wafer substrate on which the process of forming the driving circuit layer 120 is performed, the manufacturing yield may be improved. For example, because a high-cost semiconductor process is performed to manufacture the driving part 100, such improvement in the manufacturing yield of the driving part 100 may lead to cost reduction. Further, in the display part 200, because a large number of light-emitting elements can be formed on the second single-crystal semiconductor substrate 210 having a relatively large area, a high-resolution display device may be implemented.

According to one or more embodiments, the display device 10 may include the connection wiring layer 500 located between the second single-crystal semiconductor substrate 210 of the display part 200 and the driving circuit layer 120 of the driving part 100. The connection wiring layer 500 may be located on the bottom surface of the second single-crystal semiconductor substrate 210. The connection wiring layer 500 may include the plurality of routing lines RM (RM1, RM2, RM3, RM4, and RMF), and the routing lines RM may connect the sub-pixel circuit portion 220 located in the display part 200, the light-emitting elements of the display element layer 230, and the circuit board 300 to the driving part 100. The driving circuit layer 120 of the driving part 100 may be electrically connected to the display part 200 and to the circuit board 300 through the routing lines RM of the connection wiring layer 500 to transmit an electrical signal for light emission.

A first routing line RM1 may be connected to the display element layer 230 located in the display part 200. The first routing line RM1 may be electrically connected to the light-emitting element of the display element layer 230 and the pixel circuit portion 800 of the driving part 100. The first routing line RM1 may be a wire that transmits a circuit signal suitable for light emission of the light-emitting elements included in the display element layer 230.

A second routing line RM2, a third routing line RM3, and a fourth routing line RM4 may each be connected to the sub-pixel circuit portion 220 of the display part 200. The second routing line RM2 may be electrically connected to some circuit elements (e.g., the second transistor T2) located in the sub-pixel circuit portion 220 and constituting the pixel circuit PXC, and to the pixel circuit portion 800 of the driving part 100. The second routing line RM2 may be a wire that connects the second transistor T2 located in the sub-pixel circuit portion 220 to the pixel circuit PXC of the pixel circuit portion 800.

The third routing line RM3 may be electrically connected to the first terminals TD1 located in the sub-pixel circuit portion 220 and the gate driver 600 of the driving part 100. The fourth routing line RM4 may be electrically connected to the second terminals TD2 located in the sub-pixel circuit portion 220 and to the data driver 700 of the driving part 100. The third routing line RM3 and the fourth routing line RM4 may be wires for transmitting the write scan signal and the data signal from the driving part 100, respectively.

A fifth routing line RMF may be connected to the circuit board 300. The fifth routing line RMF may be electrically connected to the first pad PD1 of the driving part 100 and the second pad PD2 of the display part 200. The fifth routing line RMF may be a wire for transmitting a signal applied from the circuit board 300 to the driving part 100.

According to one or more embodiments, the display part 200 of the display device 10 may include a plurality of through holes formed in the second single-crystal semiconductor substrate 210, and the routing lines RM of the connection wiring layer 500 may be electrically connected to the sub-pixel circuit portion 220 or to the display element layer 230 through the through holes of the second single-crystal semiconductor substrate 210. The second single-crystal semiconductor substrate 210 may be located between the display element layer 230 and the driving circuit layer 120, and may include one or more through holes to provide electrical connection paths for the routing lines RM.

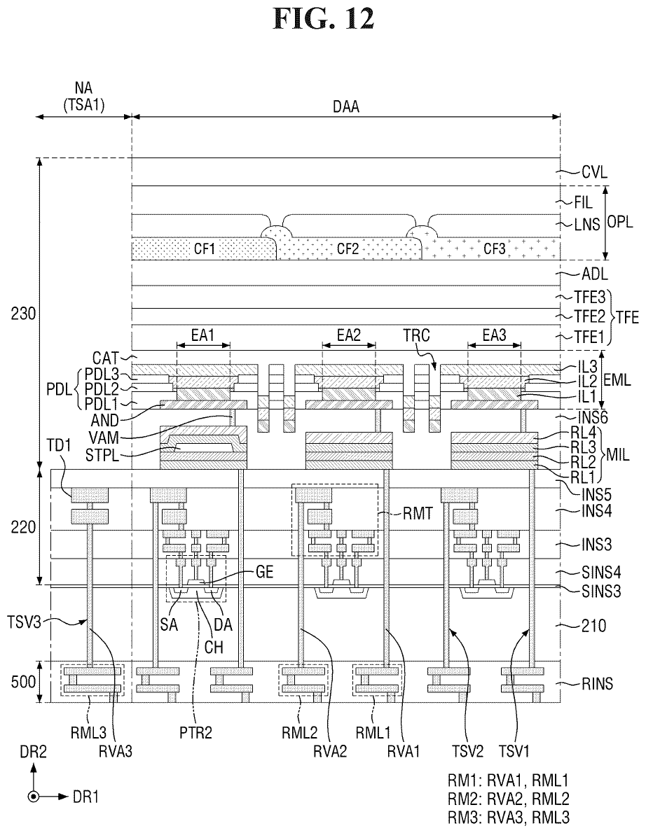

The routing lines RM may include connection lines RML1, RML2, and RML3 (see FIG. 12) located in the connection wiring layer 500, and conductive vias RVA1, RVA2, and RVA3 (see FIG. 12) located in the through holes of the second single-crystal semiconductor substrate 210. The routing lines RM may be wires that electrically connect layers positioned above and below the second single-crystal semiconductor substrate 210, and the arrangement and design of the through holes formed in the second single-crystal semiconductor substrate 210 may vary depending on the arrangement of the layers electrically connected to the routing lines RM.

For example, in the one or more embodiments corresponding to FIG. 9, because the area of the second single-crystal semiconductor substrate 210 is greater than that of the first single-crystal semiconductor substrate 110 in plan view, some sub-pixels SP included in the display element layer 230 of the display part 200 may overlap the pixel circuit portion 800 in the thickness direction, while some other sub-pixels SP might not overlap the pixel circuit portion 800 in the thickness direction.

The first routing line RM1 may be electrically connected to the light-emitting elements LE located in the plurality of sub-pixels SP of the display element layer 230 and to the pixel circuit portion 800 of the driving part 100. The conductive vias RVA1 (see FIG. 12) of the first routing line RM1 may be arranged to overlap the display element layer 230 of the display part 200 in the thickness direction, and among the plurality of through holes formed in the second single-crystal semiconductor substrate 210, the through hole(s) TSV1 (see FIG. 12) in which the first routing line RM1 is located may also overlap the display element layer 230 in the thickness direction. The connection line RML1 (see FIG. 12) of the first routing line RM1 may be electrically connected to the conductive via RVA1 and to the pixel circuit portion 800 of the driving part 100. At least the end of the connection line RML1 connected to the pixel circuit portion 800 may overlap the driving part 100.

In one or more embodiments, some of the conductive vias RVA1 (see FIG. 12) and the through holes TSV1 (see FIG. 12) in which the first routing line RM1 is located may be arranged to overlap the driving part 100, and some others might not overlap the driving part 100. For example, in one or more embodiments where the display area DAA of the display part 200 has a larger size in plan view than the driving part 100, at least some of the conductive vias RVA1 (see FIG. 12) and the through holes TSV1 (see FIG. 12) in which the first routing line RM1 is located might not overlap the driving part 100.

The second routing line RM2 may be electrically connected to some circuit elements (e.g., the second transistor T2) of the pixel circuit PXC of the sub-pixel circuit portion 220 and to the pixel circuit portion 800 of the driving part 100. The conductive vias RVA2 (see FIG. 12) of the second routing line RM2 may be arranged to overlap the sub-pixel circuit portion 220 of the display part 200 in the thickness direction, and among the plurality of through holes formed in the second single-crystal semiconductor substrate 210, the through holes TSV2 (see FIG. 12) in which the second routing line RM2 is located may also overlap the sub-pixel circuit portion 220 in the thickness direction. The connection line RML2 (see FIG. 12) of the second routing line RM2 may be electrically connected to the conductive via RVA2 and the pixel circuit portion 800 of the driving part 100. At least the ends of the connection lines RML2 connected to the pixel circuit portion 800 may overlap the driving part 100.

In one or more embodiments, some of the conductive vias RVA2 (see FIG. 12) and the through holes TSV2 (see FIG. 12) in which the second routing line RM2 is located may be arranged to overlap the driving part 100, and some others might not overlap the driving part 100. For example, in one or more embodiments where the sub-pixel circuit portion 220 of the display part 200 has a larger area in plan view than the driving part 100, at least some of the conductive vias RVA2 (see FIG. 12) and the through holes TSV2 (see FIG. 12) in which the second routing line RM2 is located might not overlap the driving part 100.

The third routing line RM3 and the fourth routing line RM4 may be electrically connected to the sub-pixel circuit portion 220 and to the gate driver 600 or the data driver 700 of the driving part 100. The conductive vias RVA3 (see FIG. 12) of the third routing line RM3 may be arranged in the first through hole area TSA1 located in the non-display area NA of the display part 200, and the conductive vias of the fourth routing line RM4 may be arranged in the second through hole area TSA2 located in the non-display area NA of the display part 200. Accordingly, the conductive via RVA3 (see FIG. 12) of the third routing line RM3 and the third through hole TSV3 (see FIG. 12) in which the third routing line RM3 is located might not overlap the driving part 100 in the thickness direction. However, because the connection line RML3 (see FIG. 12) of the third routing line RM3 is connected to the conductive via RVA3 and the driving part 100, at least the end of the connection line RML3 connected to the gate driver 600 may overlap the driving part 100. The description of the through hole TSV3 and the arrangement of the third routing line RM3 may be equally applicable to the fourth routing line RM4.

The conductive vias of the fifth routing line RMF may be arranged to overlap the first pad PD1 of the driving part 100. Among the plurality of through holes formed in the second single-crystal semiconductor substrate 210, the through holes in which the fifth routing line RMF is located may also overlap the first pad PD1 in the thickness direction. The connection lines of the fifth routing line RMF may be electrically connected to the second pad PD2 of the display part 200 to form a path for electrical connection to the conductive vias connected to the first pad PD1.

However, the present disclosure is not limited thereto. The arrangement and connection design of the plurality of routing lines RM may be modified in various ways.

The passivation layer 900 may be located around the driving part 100. The passivation layer 900 may be located on the bottom surface of the display part 200 while surrounding the driving part 100. The passivation layer 900 may be formed to cover the driving part 100 in the manufacturing process of the display device 10 to fill the step between the driving part 100 and the display part 200. In the manufacturing process of the display device 10, if the first single-crystal semiconductor substrate 110 is attached to the bottom surface of the second single-crystal semiconductor substrate 210, whose area is different from that of the first single-crystal semiconductor substrate 110, the passivation layer 900 may fill the step between the first single-crystal semiconductor substrate 110 and the second single-crystal semiconductor substrate 210, and an additional process may be performed on the second single-crystal semiconductor substrate 210.

In one or more embodiments, the thickness of the passivation layer 900 may be greater than the thickness of the first single-crystal semiconductor substrate 110. The passivation layer 900 may be thicker than or equal to the sum of the thicknesses of the first single-crystal semiconductor substrate 110 of the driving part 100 and the driving circuit layer 120 located thereon. The passivation layer 900 may be formed to be thicker than the driving part 100, so a part of the passivation layer 900 may be in direct contact with the bottom surface of the display part 200, while another part thereof may be in direct contact with the bottom surface of the driving part 100. Accordingly, the driving part 100 and the display part 200 may be completely covered by the passivation layer 900 on the bottom surface of the display device 10.

In addition, in plan view, the passivation layer 900 may have the same area as the second single-crystal semiconductor substrate 210, and the side surface of the passivation layer 900 may be parallel to the side surface of the second single-crystal semiconductor substrate 210. The passivation layer 900 may be separated along with the second single-crystal semiconductor substrate 210 upon separating the second single-crystal semiconductor substrate 210 from a wafer substrate in the manufacturing process of the display device 10. The area of the passivation layer 900 in plan view may be equal to the area of the second single-crystal semiconductor substrate 210 in plan view. Even if the display device 10 includes the first single-crystal semiconductor substrate 110 and the second single-crystal semiconductor substrate 210 having the different areas in plan view, all partial steps may be compensated by the passivation layer 900 to ensure structural stability.

Hereinafter, the structure of the driving circuit layer 120 of the driving part 100 and the display element layer 230 of the display part 200 will be described in detail with reference to other drawings.

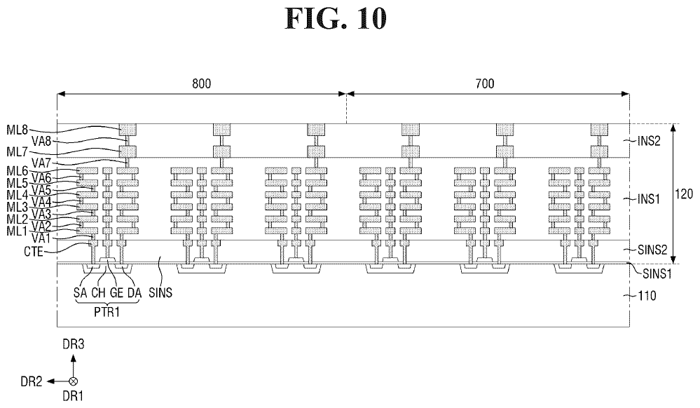

FIG. 10 is a schematic cross-sectional view of a driving part according to one or more embodiments.

Referring to FIG. 10, the driving part 100 may include the first single-crystal semiconductor substrate 110 and the driving circuit layer 120 located thereon. FIG. 10 schematically shows the cross-sectional structure of the data driver 700 and the pixel circuit portion 800 among the circuit portions located in the driving part 100.

The first single-crystal semiconductor substrate 110 may be a silicon substrate, a germanium substrate, or a silicon-germanium substrate. The first single-crystal semiconductor substrate 110 may be a substrate doped with a first type impurity. A plurality of well regions may be located on the top surface of the first single-crystal semiconductor substrate 110. The plurality of well regions may be regions doped with a second type impurity. The second type impurity may be different from the aforementioned first type impurity. For example, if the first type impurity is a p-type impurity, the second type impurity may be an n-type impurity. Alternatively, if the first type impurity is an n-type impurity, the second type impurity may be a p-type impurity.

The first single-crystal semiconductor substrate 110 may include a plurality of first transistors PTR1 constituting a plurality of circuit elements of the driving part 100. Each of the well regions formed on the first single-crystal semiconductor substrate 110 may include a source region SA corresponding to the source electrode of the first transistor PTR1, a drain region DA corresponding to the drain electrode of the transistor PTR, and a channel region CH located between the source region SA and the drain region DA.

In one or more embodiments where the first single-crystal semiconductor substrate 110 is doped with the first type impurity, each of the source region SA and the drain region DA may be doped with the first type impurity. A gate electrode GE may overlap the well region between the source region SA and the drain region DA, and the channel region CH may be formed between the source region SA and the drain region DA (e.g., in plan view). A part of a first semiconductor insulating layer SINS1 may overlap the gate electrode GE, and may be located between the gate electrode GE and the well region. In some embodiments, both ends of the gate electrode GE and the portion of the first semiconductor insulating layer SINS1 overlapping the gate electrode GE may partially overlap the source region SA and the drain region DA, respectively. The first transistors PTR1 constituting the pixel circuit portion 800 shown in the drawing may be one of the transistors constituting the pixel circuit PXC of FIG. 5, and may be any one of the first transistor T1, the third transistor T3, or the fourth transistor T4 located in the driving part 100. The transistors of the data driver 700 may be transistors constituting circuits, such as the timing control circuit 410 and the power supply circuit 420.

When the driving circuit layer 120 is formed on a silicon wafer substrate, a process of reducing the thickness of the first single-crystal semiconductor substrate 110 may be performed. The first single-crystal semiconductor substrate 110 may have a thickness that is less than that of a wafer substrate on which a semiconductor process for forming the driving circuit layer 120 is performed. In some embodiments, the thickness of the first single-crystal semiconductor substrate 110 may be about 100 μm or less, for example, in the range of about 80 μm to about 100 μm.

The driving circuit layer 120 may include the first semiconductor insulating layer SINS1, a second semiconductor insulating layer SINS2, a plurality of contact electrodes CTE, a first interlayer insulating layer INS1, a second interlayer insulating layer INS2, a plurality of conductive layers ML1, ML2, ML3, ML4, ML5, ML6, ML7, and ML8, and a plurality of vias VA1, VA2, VA3, VA4, VA5, VA6, VA7, and VA8. The driving circuit layer 120 may include wires electrically connected to the plurality of first transistors PTR1 included in the first single-crystal semiconductor substrate 110.

The first semiconductor insulating layer SINS1 and the second semiconductor insulating layer SINS2 may be located on the first single-crystal semiconductor substrate 110 (as used herein, “on” may mean “above” or “over”). The first semiconductor insulating layer SINS1 may be an insulating layer located on the first single-crystal semiconductor substrate 110, and the second semiconductor insulating layer SINS2 may be an insulating layer located on the gate electrode GE of the first transistor PTR1. The first semiconductor insulating layer SINS1 and the second semiconductor insulating layer SINS2 may be formed of a silicon carbon nitride (SiCN) or silicon oxide (SiOₓ)-based inorganic layer, but are not limited thereto. In the drawing, the first semiconductor insulating layer SINS1 and the second semiconductor insulating layer SINS2 are each shown as a single layer having a corresponding thickness (e.g., predetermined thickness), but are not limited thereto. The first semiconductor insulating layer SINS1 and the second semiconductor insulating layer SINS2 may have a structure in which one or more layers are stacked on top of each other.

The plurality of contact electrodes CTE may be located on the first single-crystal semiconductor substrate 110. The plurality of contact electrodes CTE may be connected to any one of the gate electrodes GE, the source region SA, or the drain region DA of each first transistor PTR1 formed on the first single-crystal semiconductor substrate 110 through holes penetrating the semiconductor insulating layers SINS1 and SINS2. The plurality of contact electrodes CTE may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. The top surfaces of the plurality of contact electrodes CTE may be exposed without being covered by the semiconductor insulating layers SINS1 and SINS2.

The first interlayer insulating layer INS1 may be located on the plurality of contact electrodes CTE and the semiconductor insulating layers SINS1 and SINS2. The second interlayer insulating layer INS2 may be located on the first interlayer insulating layer INS1. Each of the first interlayer insulating layer INS1 and the second interlayer insulating layer INS2 may be formed of silicon carbonitride (SiCN) or a silicon oxide (SiOₓ)-based inorganic layer, but is not limited thereto. Although it is illustrated in the drawings that each of the first interlayer insulating layer INS1 and the second interlayer insulating layer INS2 is formed as a single layer, the present disclosure is not limited thereto. Each of the first interlayer insulating layer INS1 and the second interlayer insulating layer INS2 may have a structure in which one or more layers are stacked on top of each other, and may be located between the plurality of first to eighth conductive layers ML1, ML2, ML3, ML4, ML5, ML6, ML7, and ML8 to be described later.

The first to eighth conductive layers ML1, ML2, ML3, ML4, ML5, ML6, ML7, and ML8 and the first to eighth vias VA1, VA2, VA3, VA4, VA5, VA6, VA7, and VA8 may be electrically connected to the plurality of contact electrodes CTE, and may form the pixel circuit portion 800 or the driving circuit portion 400 and the drivers 600 and 700 of the driving part 100. The plurality of first transistors PTR1 formed on the first single-crystal semiconductor substrate 110 may be electrically connected to each other through the first to eighth conductive layers ML1, ML2, ML3, ML4, ML5, ML6, ML7, and ML8 and the first to the eighth vias VA1, VA2, VA3, VA4, VA5, VA6, VA7, and VA8, and may form the driving circuit portion 400, the gate driver 600, the data driver 700, and the pixel circuit portion 800 of the driving part 100. For example, the first transistor T1, the third transistor T3, and the fourth transistor T4 included in the pixel circuit PXC of the sub-pixel SP shown in FIG. 5 may be the plurality of first transistors PTR1 included in the first single-crystal semiconductor substrate 110, and the first and second capacitors C1 and C2 and the connection of the transistors T1, T3, and T4 may be formed through the first to eighth conductive layers ML1, ML2, ML3, ML4, ML5, ML6, ML7, and ML8.

The first conductive layer ML1 may be connected to the contact electrode CTE through the first via VA1. The first conductive layer ML1 may be located on the contact electrode CTE, and the first via VA1 may be located between the first conductive layer ML1 and the contact electrode CTE to be in contact with both of them.

The second conductive layer ML2 may be connected to the first conductive layer ML1 through the second via VA2. The second conductive layer ML2 may be located on the first conductive layer ML1, and the second via VA2 may be located between the first conductive layer ML1 and the second conductive layer ML2 to be in contact with both of them.

The third conductive layer ML3 may be connected to the second conductive layer ML2 through the third via VA3. The fourth conductive layer ML4 may be connected to the third conductive layer ML3 through the fourth via VA4. The fifth conductive layer ML5 may be connected to the fourth conductive layer ML4 through the fifth via VA5. The sixth conductive layer ML6 may be connected to the fifth conductive layer ML5 through the sixth via VA6.

The third conductive layer ML3, the fourth conductive layer ML4, the fifth conductive layer ML5, and the sixth conductive layer ML6 may be sequentially located on the second conductive layer ML2. The third via VA3, the fourth via VA4, the fifth via VA5, and the sixth via VA6 may be respectively located among or between the third to sixth conductive layers ML3, ML4, ML5, and ML6. The third to sixth vias VA3, VA4, VA5, and VA6 may be in contact with different metal layers located above and below them, respectively. The seventh via VA7 may be located on the sixth conductive layer ML6. The seventh via VA7 may be in contact with the seventh conductive layer ML7 and the sixth conductive layer ML6 located thereon.

The first to sixth conductive layers ML1, ML2, ML3, ML4, ML5, and ML6 and the first to seventh vias VA1, VA2, VA3, VA4, VA5, VA6, and VA7 may be located in the first interlayer insulating layer INS1. The first to sixth conductive layers ML1, ML2, ML3, ML4, ML5, and ML6 and the first to seventh vias VA1, VA2, VA3, VA4, VA5, VA6, and VA7 may constitute a first driving circuit layer located in the first interlayer insulating layer INS1 of the driving circuit layer 120.

The seventh conductive layer ML7 may be connected to the sixth conductive layer ML6 through the seventh via VA7. The seventh conductive layer ML7 may be located on the first interlayer insulating layer INS1 and the sixth conductive layer ML6.

The seventh via VA7 may be located between the sixth conductive layer ML6 and the seventh conductive layer ML7 to be in contact therewith. The eighth conductive layer ML8 may be connected to the seventh conductive layer ML7 through the eighth via VA8. The eighth conductive layer ML8 is located on the seventh conductive layer ML7. The eighth via VA8 may be located between the seventh conductive layer ML7 and the eighth conductive layer ML8 to be in contact therewith. The top surface of the eighth conductive layer ML8 may be exposed without being covered by the second interlayer insulating layer INS2, and may be electrically connected to the routing lines RM located in the display part 200.

The seventh conductive layer ML7, the eighth via VA8, and the eighth conductive layer ML8 may be located in the second interlayer insulating layer INS2. The seventh conductive layer ML7, the eighth via VA8, and the eighth conductive layer ML8 may constitute a second driving circuit layer located in the second interlayer insulating layer INS2 of the driving circuit layer 120.

In the drawings, although the first to eighth conductive layers ML1, ML2, ML3, ML4, ML5, ML6, ML7, and ML8 and the first to eighth vias VA1, VA2, VA3, VA4, VA5, VA6, VA7, and VA8 are illustrated as being sequentially stacked on top of each other, their layout and connection may be modified in various ways according to the circuits of the driving circuit portion 400, the gate driver 600, the data driver 700, and the pixel circuit portion 800 of the driving part 100. The connection structure shown in the drawings is merely one example, and the connection of the driving circuit layer 120 located in the driving part 100 of the display device 10 is not limited thereto. In addition, the driving circuit layer 120 may not necessarily include first to eighth conductive layers ML1, ML2, ML3, ML4, ML5, ML6, ML7, and ML8 and the first to eighth vias VA1, VA2, VA3, VA4, VA5, VA6, VA7, and VA8, and some of these layers may be omitted, or more layers may be provided.

The first to eighth conductive layers ML1, ML2, ML3, ML4, ML5, ML6, ML7, and ML8 and the first to eighth vias VA1, VA2, VA3, VA4, VA5, VA6, VA7, and VA8 may be formed of substantially the same material. For example, the first to eighth conductive layers ML1, ML2, ML3, ML4, ML5, ML6, ML7, and ML8 and the first to eighth vias VA1, VA2, VA3, VA4, VA5, VA6, VA7, and VA8 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them.

The thicknesses of the first conductive layer ML1, the second conductive layer ML2, the third conductive layer ML3, the fourth conductive layer ML4, the fifth conductive layer ML5, and the sixth conductive layer ML6 may be greater than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be approximately 1360 Å. The thickness of each of the second conductive layer ML2, the third conductive layer ML3, the fourth conductive layer ML4, the fifth conductive layer ML5, and the sixth conductive layer ML6 may be approximately 1440 Å. The thickness of each of the first via VA1, the second via VA2, the third via VA3, the fourth via VA4, the fifth via VA5, and the sixth via VA6 may be approximately 1150 Å.

The thickness of each of the seventh conductive layer ML7 and the eighth conductive layer ML8 may be greater than the thickness of the first conductive layer ML1, the thickness of the second conductive layer ML2, the thickness of the third conductive layer ML3, the thickness of the fourth conductive layer ML4, the thickness of the fifth conductive layer ML5, or the thickness of the sixth conductive layer ML6. The thickness of the seventh conductive layer ML7 and the thickness of the eighth conductive layer ML8 may be greater than the thickness of the seventh via VA7 and the thickness of the eighth via VA8, respectively. The thickness of each of the seventh via VA7 and the eighth via VA8 may be greater than the thickness of the first via VA1, the thickness of the second via VA2, the thickness of the third via VA3, the thickness of the fourth via VA4, the thickness of the fifth via VA5, or the thickness of the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 may be approximately 9000 Å. The thickness of each of the seventh via VA7 and the eighth via VA8 may be approximately 6000 Å.

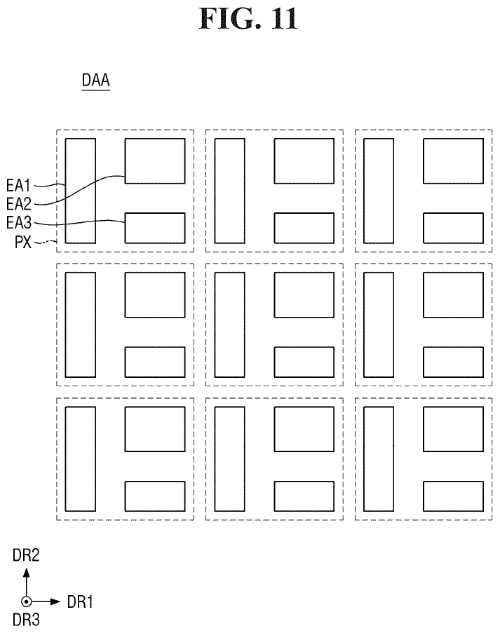

FIG. 11 is a plan view illustrating the layout of pixels located in a display area of a display part according to one or more embodiments. FIG. 12 is a cross-sectional view showing a portion of a display area and a portion of a non-display area in a display part according to one or more embodiments.

Referring to FIGS. 11 and 12, each of the plurality of pixels PX may include a first emission area EA1, a second emission area EA2, and a third emission area EA3, which are different emission areas. Each of the plurality of emission areas EA1, EA2, and EA3 may correspond to one sub-pixel SP.

Each of the first emission area EA1, the second emission area EA2, and the third emission area EA3 may have, in plan view, a quadrilateral shape, such as a rectangle, a square, or a diamond. For example, the first emission area EA1 may have a rectangular shape, in plan view, having a short side in the first direction DR1 and a long side in the second direction DR2. In addition, each of the second emission area EA2 and the third emission area EA3 may have a rectangular shape, in plan view, having a long side in the first direction DR1 and a short side in the second direction DR2.

The length of the first emission area EA1 in the first direction DR1 may be less than the length of the second emission area EA2 in the first direction DR1, and may be less than the length of the third emission area EA3 in the first direction DR1. The length of the second emission area EA2 in the first direction DR1 and the length of the third emission area EA3 in the first direction DR1 may be substantially the same.

The length of the first emission area EA1 in the second direction DR2 may be greater than the sum of the length of the second emission area EA2 in the second direction DR2 and the length of the third emission area EA3 in the second direction DR2. The length of the second emission area EA2 in the second direction DR2 may be greater than the length of the third emission area EA3 in the second direction DR2.

Although it is illustrated in the drawing that each of the first emission area EA1, the second emission area EA2, and the third emission area EA3 has a rectangular shape in plan view, the present disclosure is not limited thereto. For example, each of the first emission area EA1, the second emission area EA2, and the third emission area EA3 may have a polygonal shape other than a quadrilateral shape, a circular shape, or an elliptical shape in plan view.

In each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. In addition, the second emission area EA2 and the third emission area EA3 may be adjacent to each other in the second direction DR2. The area of the first emission area EA1, the area of the second emission area EA2, and the area of the third emission area EA3 may be different.

The first emission area EA1 may emit light of a first color, the second emission area EA2 may emit light of a second color, and the third emission area EA3 may emit light of a third color. Here, the light of the first color may be light of a blue wavelength band, the light of the second color may be light of a green wavelength band, and the light of the third color may be light of a red wavelength band. For example, the blue wavelength band may be a wavelength band of light whose main peak wavelength is in the range of about 370 nm to about 460 nm, the green wavelength band may be a wavelength band of light whose main peak wavelength is in the range of about 480 nm to about 560 nm, and the red wavelength band may be a wavelength band of light whose main peak wavelength is in the range of about 600 nm to about 750 nm.

Although it is illustrated in the drawing that each of the plurality of pixels PX includes the three emission areas EA1, EA2, and EA3, the present disclosure is not limited thereto. That is, each of the plurality of pixels PX may include four emission areas.

In addition, the layout of the emission areas of the plurality of pixels PX is not limited to that illustrated in the drawing. For example, the emission areas of the plurality of pixels PX may be arranged in a stripe structure in which the emission areas are arranged in the first direction DR1, a PenTile® structure in which the emission areas are arranged in a diamond shape, or a hexagonal structure in which the emission areas having, in plan view, a hexagonal shape are arranged side by side (PenTile® and PENTILE™ are registered trademarks of Samsung Display Co., Ltd., Republic of Korea).

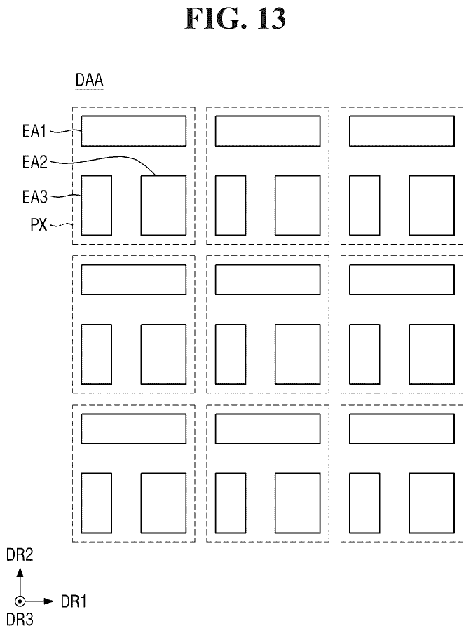

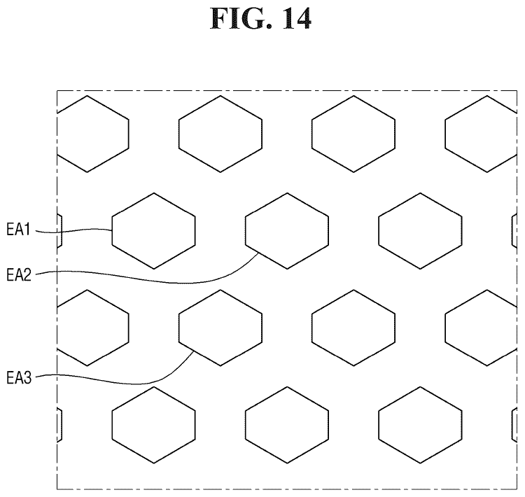

FIGS. 13 and 14 are plan views illustrating the layout of a display area of a display part according to one or more other embodiments.

Referring to FIGS. 13 and 14, in the display device 10 according to one or more embodiments, the layout of the emission areas EA1, EA2, and EA3 of the display part 200 may be different from that shown in in FIG. 10. For example, in the display device 10 of FIG. 13, the first emission area EA1 and the second emission area EA2 may be adjacent in the second direction DR2 in each of the plurality of pixels PX. Further, the first emission area EA1 and the third emission area EA3 may be adjacent to each other in the second direction DR2. Further, the second emission area EA2 and the third emission area EA3 may be adjacent to each other in the first direction DR1. The area of the first emission area EA1, the area of the second emission area EA2, and the area of the third emission area EA3 may be different. Although the first emission area EA1 in the display device 10 of FIG. 10 has a shape extending in the second direction DR2, the first emission area EA1 in the display device 10 of FIG. 10 may have a shape extending in the first direction DR1.

In the display device 10 of FIG. 14, each of the first emission area EA1, the second emission area EA2, and the third emission area EA3 may have a hexagonal shape in plan view, and they may be arranged while being spaced apart from each other in a diagonal direction. In the drawings, it is illustrated that the first emission area EA1 and the second emission area EA2 are spaced from each other in a horizontal direction, and the third emission area EA3 is spaced apart from each of the first emission area EA1 and the second emission area EA2 in a diagonal direction. However, the arrangement of the plurality of emission areas EA1, EA2, and EA3 is not limited thereto.

The display part 200 may include the second single-crystal semiconductor substrate 210, a reflective layer MIL, a light-emitting element layer EML, an encapsulation layer TFE, an optical layer OPL, and a cover layer CVL. The connection wiring layer 500 may be located between the second single-crystal semiconductor substrate 210 and the first single-crystal semiconductor substrate 110. Alternatively, the connection wiring layer 500 may be located between the light-emitting element layer EML and the first single-crystal semiconductor substrate 110.

The second single-crystal semiconductor substrate 210 may be a silicon substrate, a germanium substrate, or a silicon-germanium substrate. The second single-crystal semiconductor substrate 210 may be a substrate doped with an impurity. A plurality of well regions may be located on the top surface of the second single-crystal semiconductor substrate 210. The plurality of well regions may be regions doped with a second type impurity. The second type impurity may be different from the aforementioned first type impurity. For example, if the first type impurity is a p-type impurity, the second type impurity may be an n-type impurity. Alternatively, if the first type impurity is an n-type impurity, the second type impurity may be a p-type impurity. However, the present disclosure is not limited thereto. The second single-crystal semiconductor substrate 210 may be a silicon substrate that is not doped with an impurity.

Referring to FIG. 12, the second single-crystal semiconductor substrate 210 may include a second transistor PTR2, which a circuit element of the pixel circuit PXC. Each of the well regions formed on the second single-crystal semiconductor substrate 210 may include the source region SA corresponding to the source electrode of the second transistor PTR2, the drain region DA corresponding to the drain electrode of the transistor PTR, and the channel region CH located between the source region SA and the drain region DA. The second transistors PTR2 shown in the drawing may be one of the transistors constituting the pixel circuit PXC of FIG. 5 and may be the second transistor T2 located in the display part 200. However, the present disclosure is not limited thereto, and the second transistor PTR2 may be another transistor included in the pixel circuit PXC of FIG. 5.

On the other hand, in the display device 10, wafer substrates on which the first transistor PTR1 formed on the first single-crystal semiconductor substrate 110 of the driving part 100 are formed, and on which the second transistor PTR2 formed on the second single-crystal semiconductor substrate 210 of the display part 200 are formed, may be different. According to one or more embodiments, in the display device 10, the first transistor PTR1 formed on the first single-crystal semiconductor substrate 110 and the second transistor PTR2 formed on the second single-crystal semiconductor substrate 210 may have different sizes, line widths, and the like.

For example, in the display device 10, the minimum line width of the first transistor PTR1 formed on the first single-crystal semiconductor substrate 110 may be less than the minimum line width of the second transistor PTR2 formed on the second single-crystal semiconductor substrate 210. The semiconductor process performed on the first wafer substrate for the formation of the first transistor PTR1 is a process having higher resolution than the semiconductor process performed on the second wafer substrate for the formation of the second transistor PTR2. Thus, the size of an element, such as a manufactured transistor, may be smaller. In other words, the semiconductor process performed on the first wafer substrate may be a finer process than the semiconductor process performed on the second wafer substrate.

As described above, the first single-crystal semiconductor substrate 110 of the driving part 100 may have a smaller area in plan view than the second single-crystal semiconductor substrate 210 of the display part 200, and small-sized elements may be arranged with a high integration density to reduce power consumption and improve manufacturing yield. On the other hand, the second single-crystal semiconductor substrate 210 of the display part 200 may have a larger area in plan view than the first single-crystal semiconductor substrate 110, and a process with a relatively large linewidth may be performed. The second transistors PTR2 located in the second single-crystal semiconductor substrate 210 may be formed in a larger area than when formed in the first single-crystal semiconductor substrate 110, and the second transistors PTR2 constituting the pixel circuit PXC may not require a high integration density. Accordingly, the semiconductor process performed on the first wafer substrate may be performed as a high-cost process having a small line width, and the semiconductor process performed on the second wafer substrate may be performed as a low-cost process having a relatively large line width.

In one or more embodiments, the lengths of the channel regions CH of the plurality of transistors PTR1 and PTR2 may be different from each other, and the minimum line width or a length of the channel region CH of the first transistor PTR1 may be less than the minimum line width or a length of the channel region CH of the second transistor PTR2. The minimum line width or the length of the channel region CH of the first transistor PTR1 may be equal to or less than about 100 nm, or may range from about 2 nm to about 80 nm. The minimum line width or the length of the channel region CH of the second transistor PTR2 may be greater than or equal to about 100 nm, or may range from about 100 nm to about 5 μm.

The second single-crystal semiconductor substrate 210 may include the plurality of through holes TSV1, TSV2, and TSV3 spaced apart from each other. The through holes TSV1, TSV2, and TSV3 may penetrate from the top surface of the second single-crystal semiconductor substrate 210 to the bottom surface thereof, and the conductive vias RVA1, RVA2, and RVA3 of the routing lines RM1, RM2, and RM3 may be located therein. The through holes TSV1, TSV2, and TSV3 may form connection paths for the routing lines RM1, RM2, and RM3 to electrically connect the driving part 100 to the sub-pixel circuit portion 220 or the light-emitting element of the display part 200. In some embodiments, the through holes TSV1, TSV2, and TSV3 of the second single-crystal semiconductor substrate 210 may be formed through a through silicon via (TSV) process in which a hole that penetrates the wafer substrate is formed. Through the through holes TSV1, TSV2, and TSV3 formed in the second single-crystal semiconductor substrate 210, the display element layer 230 and the driving part 100 may be electrically connected to each other through the routing lines RM1, RM2 and RM3 without an additional wire.

A process of reducing the thickness of the second single-crystal semiconductor substrate 210 may be performed after the driving part 100 is bonded onto the silicon wafer substrate. The second single-crystal semiconductor substrate 210 may have a thickness greater than that of the wafer substrate on which a process for forming conductive layers is performed. In some embodiments, the thickness of the second single-crystal semiconductor substrate 210 may be about 100 μm or less, for example, in the range of about 80 μm to about 100 μm.

The sub-pixel circuit portion 220 may be located on the second single-crystal semiconductor substrate 210. The sub-pixel circuit portion 220 may include a third semiconductor insulating layer SINS3, a fourth semiconductor insulating layer SINS4, a third interlayer insulating layer INS3, a fourth interlayer insulating layer INS4, contact electrodes of the second transistor PTR2, and a plurality of routing conductive layers RMT. The sub-pixel circuit portion 220 may include wires electrically connected to the plurality of second transistors PTR2 formed in the second single-crystal semiconductor substrate 210, and the first scan line GWL, the data line DL, and the terminals TD1 and TD2 located in the display part 200.

The sub-pixel circuit portion 220 of the display part 200 may have a structure similar to the driving circuit layer 120 of the driving part 100. For example, the third semiconductor insulating layer SINS3 and the fourth semiconductor insulating layer SINS4 may be located on the second single-crystal semiconductor substrate 210. The third semiconductor insulating layer SINS3 may be an insulating layer located on the second single-crystal semiconductor substrate 210, and the fourth semiconductor insulating layer SINS4 may be an insulating layer located on the gate electrode GE of the second transistor PTR2. The third semiconductor insulating layer SINS3 and the fourth semiconductor insulating layer SINS4 may be formed of a silicon carbon nitride (SiCN) or silicon oxide (SiOₓ)-based inorganic layer, but are not limited thereto.

The plurality of contact electrodes connected to the second transistor PTR2 may be located on the second single-crystal semiconductor substrate 210. The plurality of contact electrodes may be connected to any one of the gate electrode, the source region, or the drain region of each of the second transistors PTR2 formed in the second single-crystal semiconductor substrate 210 through holes penetrating the semiconductor insulating layers SINS3 and SINS4.

The third interlayer insulating layer INS3 may be located on the plurality of contact electrodes and the semiconductor insulating layers SINS3 and SINS4. The fourth interlayer insulating layer INS4 may be located on the third interlayer insulating layer INS3. Each of the third interlayer insulating layer INS3 and the fourth interlayer insulating layer INS4 may be formed of silicon carbonitride (SiCN) or a silicon oxide (SiOₓ)-based inorganic layer, but is not limited thereto.

The routing conductive layer RMT may have a structure similar to the plurality of conductive layers ML1, ML2, ML3, ML4, ML5, ML6, ML7, and ML8 and the vias VA1, VA2, VA3, VA4, VA5, VA6, VA7, and VA8 of the driving circuit layer 120. The routing conductive layer RMT may include one or more conductive layers and vias located between them to form the terminals TD1 and TD2 or the wires located in the display part 200. For example, the routing conductive layers RMT of the sub-pixel circuit portion 220 located in the display area DAA may be electrically connected to the second transistor PTR2. The second transistor PTR2 shown in FIG. 12 may be the second transistor T2 included in the pixel circuit PXC of FIG. 5. The routing conductive layers RMT may serve as connection lines that connect the second transistor PTR2 to other circuit elements. In addition, in one or more embodiments, some of the routing conductive layers RMT of the sub-pixel circuit portion 220 located in the display area DAA may be the first scan lines GWL or the data lines DL.

The sub-pixel circuit portion 220 may include the plurality of terminals TD1 in the non-display area NA. The terminals TD1 may be electrically connected to the first scan lines GWL or the data lines DL located in the display area DAA.

The connection wiring layer 500 may be located on the bottom surface of the second single-crystal semiconductor substrate 210. The connection wiring layer 500 may include an interlayer insulating layer RINS and the plurality of connection lines RML1, RML2, and RML3.

The interlayer insulating layer RINS may be located on the bottom surface of the second single-crystal semiconductor substrate 210. The interlayer insulating layer RINS may be formed of a silicon carbon nitride (SiCN) or silicon oxide (SiOₓ)-based inorganic layer, but is not limited thereto. In the drawing, the interlayer insulating layer RINS is illustrated as a single layer, but is not limited thereto and may have a structure in which one or more layers are stacked on top of each other, and they may be located between the connection lines RML1, RML2, and RML3.

The connection lines RML1, RML2, and RML3 may form the routing lines RM1, RM2, and RM3 together with the plurality of conductive vias RVA1, RVA2, and RVA3. The connection lines RML1, RML2, and RML3 may include one or more conductive layers, and one or more vias connecting them to each other. The connection and structure of the connection lines RML1, RML2, and RML3 may be the same as described above for the conductive layers ML1, ML2, ML3, ML4, ML5, ML6, ML7, and ML8 and the vias VA1, VA2, VA3, VA4, VA5, VA6, VA7, and VA8. The connection lines RML1, RML2, and RML3 may be electrically connected to the light-emitting elements of the light-emitting element layer EML or the sub-pixel circuit portion 220 through the conductive vias RVA1, RVA2, and RVA3 located in the through holes TSV1, TSV2, and TSV3 of the second single-crystal semiconductor substrate 210, and may be electrically connected to the driving circuit layer 120 of the driving part 100.

According to one or more embodiments, the display part 200 of the display device 10 may include the first through hole TSV1, the second through hole TSV2, and the third through hole TSV3 that penetrate the second single-crystal semiconductor substrate 210. The first through hole TSV1 and the second through hole TSV2 may be located in the display area DAA, and the third through hole TSV3 may be located in the non-display area NA (e.g., the first through hole area TSA1). In addition, in one or more embodiments, the display device 10 may further include the fourth through hole TSV4 located in the second through hole area TSA2 of the non-display area NA.

The first routing line RM1 that connects the light-emitting element of the light-emitting element layer EML, which will be described later, to the driving circuit layer 120 of the driving part 100 may be located in the first through hole TSV1. The first routing line RM1 may include a first conductive via RVA1 located in the first through hole TSV1, and a first connection line RML1 located in the connection wiring layer 500. The first through hole TSV1 may penetrate the second single-crystal semiconductor substrate 210, the semiconductor insulating layers SINS3 and SINS4, and the interlayer insulating layers INS3, INS4, and INS5 to extend from the bottom surface of the reflective layer MIL, which will be described later, to the bottom surface of the second single-crystal semiconductor substrate 210. The first conductive via RVA1 may also be located from the bottom surface of the reflective layer MIL to the bottom surface of the second single-crystal semiconductor substrate 210 to be connected to each of the reflective layer MIL and the first connection line RML1. The first routing line RM1 may connect the light-emitting element of the light-emitting element layer EML to the pixel circuit portion 800 of the driving part 100.

The second routing line RM2 that connects the second transistor PTR2 of the routing conductive layer RMT of the sub-pixel circuit portion 220 to the driving circuit layer 120 of the driving part 100 may be located in the second through hole TSV2. The second routing line RM2 may include a second conductive via RVA2 located in the second through hole TSV2, and a second connection line RML2 located in the connection wiring layer 500. The second through hole TSV2 may penetrate the second single-crystal semiconductor substrate 210, the semiconductor insulating layers SINS3 and SINS4, and a portion of the interlayer insulating layers INS3 and INS4 to extend from the bottom surface of any conductive layer of the routing conductive layer RMT to the bottom surface of the second single-crystal semiconductor substrate 210. The second conductive via RVA2 may also be located from the bottom surface of any conductive layer of the routing conductive layer RMT to the bottom surface of the second single-crystal semiconductor substrate 210 to be connected to each of the routing conductive layer RMT and the second connection line RML2. The second routing line RM2 may connect the second transistor PTR2 located in the display part 200 to the pixel circuit PXC located in the pixel circuit portion 800 of the driving part 100.

The third routing line RM3 that connects the terminal TD1 of the sub-pixel circuit portion 220 to the driving circuit layer 120 of the driving part 100 may be located in the third through hole TSV3. The third routing line RM3 may include a third conductive via RVA3 located in the third through hole TSV3, and a third connection line RML3 located in the connection wiring layer 500. The third through hole TSV3 may penetrate the second single-crystal semiconductor substrate 210, the semiconductor insulating layers SINS3 and SINS4, and a portion of the interlayer insulating layers INS3 and INS4 to extend from the bottom surface of the terminal TD1 to the bottom surface of the second single-crystal semiconductor substrate 210. The third conductive via RVA3 may also be located from the bottom surface of the terminal TD1 to the bottom surface of the second single-crystal semiconductor substrate 210 to be connected to each of the terminal TD1 and the third connection line RML3. The third routing line RM3 may connect the first scan line GWL or the data line DL to the driving circuit layer 120 or to the gate driver 600 or the data driver 700 of the driving part 100 through the terminals TD1 located in the display part 200.

According to one or more embodiments, at least some of the through holes TSV1, TSV2, and TSV3, the connection lines RML1, RML2, and RML3, and the conductive vias RVA1, RVA2, and RVA3 may be located in the display area DAA. For example, the first through hole TSV1, the second through hole TSV2, the first conductive via RVA1, and the second conductive via RVA2 may be located in the display area DAA. Among them, the first through hole TSV1 and the first conductive via RVA1 may overlap the emission areas EA1, EA2, and EA3 of the light-emitting element layer EML in the thickness direction. The second through hole TSV2 and the second conductive via RVA2 may overlap the emission areas EA1, EA2, and EA3 of the light-emitting element layer EML in some cases, but are not limited thereto. The drawing illustrates a case where the second through hole TSV2 and the second conductive via RVA2 do not overlap the emission areas EA1, EA2, and EA3 of the light-emitting element layer EML.

Further, the third through hole TSV3 and the third conductive via RVA3 may overlap the non-display area NA. As described above, the third through hole TSV3 may be located in the through hole area TSA1 of the non-display area NA, and the third through hole TSV3 and the third conductive via RVA3 might not overlap the display area DAA. The same may be true for the fourth through hole TSV4 and the conductive via of the fourth routing line RM4, in one or more embodiments.

Some of the connection lines RML1, RML2, and RML3 may be located in the display area DAA and some others may be located in the non-display area NA. For example, the first connection line RML1 and the second connection line RML2 may be located in the display area DAA, and the third connection line RML3 may be located in the non-display area NA. Some of the connection lines RML1, RML2, and RML3 located in the display area DAA may overlap the light-emitting element layer EML. The connection line of the fourth routing line RM4 may also be located in the non-display area NA, in one or more embodiments.

Because the routing lines RM1, RM2, and RM3 electrically connect the elements located on the second single-crystal semiconductor substrate 210 to the driving circuit layer 120 located on the first single-crystal semiconductor substrate 110, the arrangement of the connection lines RML1, RML2, and RML3, the through holes TSV1, TSV2, and TSV3, and the conductive vias RVA1, RVA2, and RVA3 may be modified in various ways depending on their relative arrangement with respect to the light-emitting element layer EML and the first single-crystal semiconductor substrate 110.

For example, the connection wiring layer 500 may be located on the bottom surface of the second single-crystal semiconductor substrate 210, the through holes TSV1, TSV2, and TSV3 and the conductive vias RVA1, RVA2, and RVA3 may be arranged across the entire second single-crystal semiconductor substrate 210, and the connection lines RML1, RML2, and RML3 may be arranged across the entire second single-crystal semiconductor substrate 210, but may be concentrated in a region where the first single-crystal semiconductor substrate 110 is located. According to one or more embodiments, in the display device 10, the first through holes TSV1, the second through holes TSV2, the first conductive vias RVA1, and the second conductive vias RVA2 may be arranged in the display area DAA, and may overlap the light-emitting element layer EML in the thickness direction, and each of them may have at least a portion overlapping the first single-crystal semiconductor substrate 110 in the thickness direction. As described above, the area of the first single-crystal semiconductor substrate 110 in plan view may be less than the area of the second single-crystal semiconductor substrate 210 in plan view, and only some of the first through holes TSV1, the second through holes TSV2, the first conductive vias RVA1, and the second conductive vias RVA2 arranged across the entire second single-crystal semiconductor substrate 210 may overlap the first single-crystal semiconductor substrate 110 in the thickness direction. On the other hand, the third through holes TSV3 and the third conductive vias RVA3 may be arranged in the non-display area NA without overlapping the light-emitting element layer EML in the thickness direction, and also without overlapping the first single-crystal semiconductor substrate 110 in the thickness direction.

At least some of the connection lines RML1, RML2, and RML3 may also not overlap the first single-crystal semiconductor substrate 110 in the thickness direction. The first connection lines RML1 may electrically connect the first conductive via RVA1 located in the display area DAA to the pixel circuit portion 800 formed on the first single-crystal semiconductor substrate 110. Some of the plurality of first connection lines RML1 may overlap the first single-crystal semiconductor substrate 110 in the thickness direction, and the end of the first connection line RML1 formed of a plurality of layers may also overlap the first single-crystal semiconductor substrate 110 in the thickness direction. In addition, among the plurality of first connection lines RML1, the connection line connected to the first conductive via RVA1 that does not overlap the first single-crystal semiconductor substrate 110 might not overlap the first single-crystal semiconductor substrate 110 in the thickness direction, but the end of the first connection line RML1 formed of a plurality of layers may overlap the first single-crystal semiconductor substrate 110 in the thickness direction. Similar to the first connection lines RML1, some of the second connection lines RML2 may overlap the first single-crystal semiconductor substrate 110, and some others thereof might not overlap the first single-crystal semiconductor substrate 110. However, the end of the second connection line RML2 formed of at least a plurality of layers may overlap the first single-crystal semiconductor substrate 110 in the thickness direction.

The third connection line RML3 may electrically connect the third conductive via RVA3 located in the non-display area NA to the gate driver 600 or the data driver 700 formed on the first single-crystal semiconductor substrate 110. The plurality of third connection lines RML3 might not overlap the first single-crystal semiconductor substrate 110 in the thickness direction, but the end of the third connection line RML3 formed of a plurality of layers may overlap the first single-crystal semiconductor substrate 110 in the thickness direction. The connection lines RML1, RML2, and RML3 may form paths for electrically connecting the conductive vias RVA1, RVA2, and RVA3 located across the entire second single-crystal semiconductor substrate 210 having a larger area to the driving circuit layer 120 located on the first single-crystal semiconductor substrate 110 having a relatively small area.

In the display device 10, the circuit portions provided in the driving part 100 may be formed by a relatively high-cost micro semiconductor process, and thus may be formed with a high integration density on the first single-crystal semiconductor substrate 110 having a relatively small area. The manufacturing process of the driving part 100 may have a high yield per unit wafer substrate, and a circuit element (e.g., the first transistor) may have a small size, resulting in reduced power consumption. In addition, some wires and some circuit elements of the pixel circuit PXC for light emission of the light-emitting element may be located in the display part 200, thereby solving the problem that the integration density of the first single-crystal semiconductor substrate 110 becomes too high. Furthermore, the circuit elements arranged at a high integration density may be dividedly located in different single-crystal semiconductor substrates 110 and 210, thereby reducing or minimizing the formation of parasitic capacitance between adjacent circuit elements.

The display element layer 230 may include the reflective layer MIL, the light-emitting element layer EML, the encapsulation layer TFE, the optical layer OPL, and the cover layer CVL. The display element layer 230 may include the light-emitting elements electrically connected to the sub-pixel circuit portion 220 and the pixel circuit portion 800 of the driving part 100 to emit light.

The reflective layer MIL may be located on the second single-crystal semiconductor substrate 210. Alternatively, the reflective layer MIL may be located on the sub-pixel circuit portion 220. The reflective layer MIL may include one or more layers of reflective electrodes RL1, RL2, RL3, and RL4. Each of the plurality of reflective electrodes RL1, RL2, RL3, and RL4 of the reflective layer MIL may overlap the emission areas EA1, EA2, and EA3. When lights emitted from the light-emitting element layer EML located on the reflective layer MIL are emitted toward the second single-crystal semiconductor substrate 210, the reflective layer MIL may reflect them toward an upper portion of the display part 200. In addition, the reflective layer MIL may be formed of a conductive metal layer, and may be electrically connected to each of a first electrode AND of the light-emitting element and the connection line RML.

Each of first reflective electrodes RL1 may be located on a fifth interlayer insulating layer INS5, and may be connected to the first routing line RM1. The first reflective electrodes RL1 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them.

Each of second reflective electrodes RL2 may be located on a corresponding first reflective electrode RL1. The second reflective electrodes RL2 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the second reflective electrodes RL2 may be made of titanium nitride (TiN).

A step layer STPL may be located on the second reflective electrode RL2 overlapping the first emission area EA1. The step layer STPL may not be located on the second reflective electrodes RL2 overlapping the second emission area EA2 or the third emission area EA3. To facilitate the reflection of light emitted from intermediate layers IL1, IL2, and IL3, the thickness of the step layer STPL may be set in consideration of the wavelength of the light and a distance from a second electrode CAT of the light-emitting element to a fourth reflective electrode RL4. The step layer STPL may be formed of a silicon carbon nitride (SiCN) or silicon oxide (SiOₓ)-based inorganic layer, but is not limited thereto. The thickness of the step layer STPL may be about 400 Å.

In the first emission area EA1, a third reflective electrode RL3 may be located on the second reflective electrode RL2 and the step layer STPL. In the second emission area EA2 and the third emission area EA3, the third reflective electrode RL3 may be located on the second reflective electrode RL2. The third reflective electrodes RL3 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them.

At least one of the first reflective electrode RL1, the second reflective electrode RL2, or the third reflective electrode RL3 may be omitted.

The fourth reflective electrodes RL4 may be respectively located on the third reflective electrodes RL3. The fourth reflective electrodes RL4 may reflect light from first to third intermediate layers IL1, IL2, and IL3. Among the plurality of reflective electrodes RL1, RL2, RL3, and RL4, at least the uppermost fourth reflective electrode RL4 may include a metal having a high reflectance to facilitate light reflection. The fourth reflective electrodes RL4 may be formed of aluminum (Al), a stacked structure (Ti/Al/Ti) of aluminum and titanium, a stacked structure (ITO/Al/ITO) of aluminum and ITO, an APC alloy, which is an alloy of silver (Ag), palladium (Pd), and copper (Cu), and a stacked structure (ITO/APC/ITO) of the APC alloy and ITO, but are not limited thereto. Each of the fourth reflective electrodes RL4 may have a thickness of about 850 Å.

Meanwhile, a method of having light emitted from the intermediate layers IL1, IL2, and IL3 suitably reflected by the reflective layer MIL is not limited to providing the step layer STPL. Depending on the thickness of the fourth interlayer insulating layer INS4 located between the first electrode AND of the light-emitting element and the fourth reflective electrode RL4, the reflection of light emitted from the intermediate layers IL1, IL2, and IL3 may be suitable. In the display device 10, the thickness of a sixth interlayer insulating layer INS6 located between the first electrode AND of the light-emitting element and the fourth reflective electrode RL4 in some emission areas EA1, EA2, and EA3 may be adjusted in consideration of the wavelengths of light emitted from different emission areas EA1, EA2, and EA3.

In the display device 10 of the one or more embodiments corresponding to FIG. 12, the step layer STPL is overlapping the light-emitting element in the first emission area EA1, while the step layer STPL is not located in the second emission area EA2 and the third emission area EA3. However, the present disclosure is not limited thereto, and the step layer STPL may be further located in at least one of the second emission area EA2 or the third emission area EA3. Alternatively, the step layer

STPL may be omitted, and the thickness of the sixth interlayer insulating layer INS6 may vary between the first electrodes AND of the light-emitting elements and the fourth reflective electrodes RL4.

The sixth interlayer insulating layer INS6 may be located on the fifth interlayer insulating layer INS5 and the fourth reflective electrodes RL4. The sixth interlayer insulating layer INS6 may be formed of a silicon carbonitride (SiCN) or a silicon oxide (SiOx)-based inorganic layer, but is not limited thereto. In the drawing, it is shown that the sixth interlayer insulating layer INS6 is formed of a single layer, but is not limited thereto. The sixth interlayer insulating layer INS6 may have a structure in which one or more layers are stacked on each other.

A via VAM may be located between the fourth reflective electrode RL4 and the light-emitting element layer EML. The via VAM may be located between the fourth reflective electrode RL4 and the first electrode AND of the light-emitting element layer EML and may be connected to each of them. The via VAM may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. Due to the step layer STPL, the thickness of the via VAM overlapping the first emission area EA1 may be less than the thickness of the via VAM in each of the second emission area EA2 and the third emission area EA3. For example, the thickness of the via VAM in the first emission area EA1 may be approximately 800 Å, and the thickness of the via VAM in each of the second emission area EA2 and third emission area EA3 may be approximately 1200 Å.

The light-emitting element layer EML may be located on the sixth interlayer insulating layer INS6. The light-emitting element layer EML may include the light-emitting elements LE each having the first electrode AND, the intermediate layers IL1, IL2, and IL3, and the second electrode CAT, a pixel-defining layer PDL, and a plurality of trenches TRC.

The first electrode AND of each of the light-emitting elements LE may be located on the sixth interlayer insulating layer INS6 and may be connected to the via VAM. The first electrode AND of each of the light-emitting elements LE may be electrically connected to the pixel circuit portion 800 of the driving part 100 through the via VAM, the first to fourth reflective electrodes RL1 to RL4, and the first routing line RM1. The first electrode AND of each of the light-emitting elements LE may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the first electrode AND of each of the light-emitting elements LE may be titanium nitride (TiN).

The pixel-defining layer PDL may be located on a part of the first electrode AND of each of the light-emitting elements LE. The pixel-defining layer PDL may cover the edge of the first electrode AND of each of the light-emitting elements LE. The pixel-defining layer PDL may partition the first emission areas EA1, the second emission areas EA2, and the third emission areas EA3.

The first emission area EA1 may be defined as an area in which the first electrode AND, the intermediate layers IL1, IL2, and IL3, and the second electrode CAT are sequentially stacked in the first sub-pixel to emit light. The second emission area EA2 may be defined as an area in which the first electrode AND, the intermediate layers IL1, IL2, and IL3, and the second electrode CAT are sequentially stacked in the second sub-pixel to emit light. The third emission area EA3 may be defined as an area in which the first electrode AND, the intermediate layers IL1, IL2, and IL3, and the second electrode CAT are sequentially stacked in the third sub-pixel to emit light.

The pixel-defining layer PDL may include first to third pixel-defining layers PDL1, PDL2, and PDL3. The first pixel-defining layer PDL1 may be located on the edge of the first electrode AND of each of the light-emitting elements, the second pixel-defining layer PDL2 may be located on the first pixel-defining layer PDL1, and the third pixel-defining layer PDL3 may be located on the second pixel-defining layer PDL2.

The first pixel-defining layer PDL1, the second pixel-defining layer PDL2, and the third pixel-defining layer PDL3 may be formed of a silicon oxide (SiOₓ)-based inorganic layer, but are not limited thereto. The first pixel-defining layer PDL1, the second pixel-defining layer PDL2, and the third pixel-defining layer PDL3 may each have a thickness of about 500 Å.

Each of the plurality of trenches TRC may penetrate the first pixel-defining layer PDL1, the second pixel-defining layer PDL2, and the third pixel-defining layer PDL3. The sixth interlayer insulating layer INS6 may be partially recessed at each of the plurality of trenches TRC.

At least one trench TRC may be located between adjacent emission areas EA1, EA2, and EA3. Although FIG. 12 illustrates that two trenches TRC are located between adjacent emission areas EA1, EA2, and EA3, the present disclosure is not limited thereto. In a process of forming the intermediate layers IL1, IL2, and IL3 to be described later, the trench TRC may reduce or prevent the likelihood of the connection of the material of the intermediate layers IL1, IL2, and IL3 between different emission areas EA1, EA2, and EA3 or openings of the pixel-defining layer PDL.

The intermediate layers IL1, IL2, and IL3 may include the first intermediate layer IL1, the second intermediate layer IL2, and the third intermediate layer IL3.

The intermediate layers IL1, IL2, and IL3 may have a tandem structure including the plurality of intermediate layers IL1, IL2, and IL3 that emit different lights. For example, the intermediate layers IL1, IL2, and IL3 may include the first intermediate layer IL1 that emits light of the first color, the second intermediate layer IL2 that emits light of the third color, and the third intermediate layer IL3 that emits light of the second color. The first intermediate layer IL1, the second intermediate layer IL2, and the third intermediate layer IL3 may be sequentially stacked. The stacking order of the first to third intermediate layers IL1, IL2, and IL3 that emit lights of different colors may be varied.

The first intermediate layer IL1 may have a structure in which a first hole transport layer, a first organic light-emitting layer that emits light of the first color, and a first electron transport layer are sequentially stacked. The second intermediate layer IL2 may have a structure in which a second hole transport layer, a second organic light-emitting layer that emits light of the third color, and a second electron transport layer are sequentially stacked. The third intermediate layer IL3 may have a structure in which a third hole transport layer, a third organic light-emitting layer that emits light of the second color, and a third electron transport layer are sequentially stacked.

A first charge generation layer for supplying charges to the second intermediate layer IL2 and for supplying electrons to the first intermediate layer IL1 may be located between the first intermediate layer IL1 and the second intermediate layer IL2. A second charge generation layer for supplying charges to the third intermediate layer IL3 and for supplying electrons to the second intermediate layer IL2 may be located between the second intermediate layer IL2 and the third intermediate layer IL3.

The first intermediate layer IL1 may be located on the first electrodes AND, and may be located on the bottom surface of each trench TRC. Due to the trench TRC, the first intermediate layer IL1 may be cut off between adjacent emission areas EA1, EA2, and EA3. The second intermediate layer IL2 may be located on the first intermediate layer IL1. Due to the trench TRC, the second intermediate layer IL2 may be cut off between adjacent emission areas EA1, EA2, and EA3. The third intermediate layer IL3 may be located on the second intermediate layer IL2. Due to the trench TRC, the third intermediate layer IL3 may be cut off between adjacent emission areas EA1, EA2, and EA3. That is, each of the plurality of trenches TRC may be a structure for cutting off the first to third intermediate layers IL1, IL2, and IL3 of the light-emitting element layer EML between adjacent emission areas EA1, EA2, and EA3.

To stably cut off the first to third intermediate layers IL1, IL2, and IL3 of the light-emitting element layer EML between adjacent emission areas EA1, EA2, and EA3, the depth of each of the plurality of trenches TRC may be greater than the height of the pixel-defining layer PDL. The depth of each of the plurality of trenches TRC may be the length of the trench TRC measured in the third direction DR3. The height of the pixel-defining layer PDL may be the length of the pixel-defining layer PDL measured in the third direction DR3.

In some embodiments, another structure may be located in place of the trench TRC to cut off the first to third intermediate layers IL1, IL2, and IL3 of the light-emitting element layer EML between adjacent emission areas EA1, EA2, and EA3. For example, a reverse tapered partition wall may be located on the pixel-defining layer PDL between adjacent emission areas EA1, EA2, and EA3.

The number of the intermediate layers IL1, IL2, and IL3 that emit different lights is not limited to that shown in FIG. 9. For example, the intermediate layers IL1, IL2, and IL3 may include two intermediate layers. In this case, one of the two intermediate layers may be substantially the same as the first intermediate layer IL1, and the other may include a second hole transport layer, a second organic light-emitting layer, a third organic light-emitting layer, and a second electron transport layer. In this case, a charge generation layer for supplying electrons to one intermediate layer and for supplying charges to the other intermediate layer may be located between the two intermediate layers.

In addition, the drawing illustrates that the first to third intermediate layers IL1, IL2, and IL3 are all located in the first emission area EA1, the second emission area EA2, and the third emission area EA3, but the present disclosure is not limited thereto. For example, the first intermediate layer IL1 may be located in the first emission area EA1, and may be omitted from the second emission area EA2 and the third emission area EA3. Further, the second intermediate layer IL2 may be located in the third emission area EA3, and may be omitted from the first emission area EA1 and the second emission area EA2. Furthermore, the third intermediate layer IL3 may be located in the second emission area EA2, and may be omitted from the first emission area EA1 and the third emission area EA3. In this case, first to third color filters CF1, CF2, and CF3 of the optical layer OPL may be omitted.

The second electrode CAT may be located on the third intermediate layer IL3. The second electrode CAT may be located on the third intermediate layer IL3 in each of the plurality of trenches TRC. The second electrode CAT may be formed of a transparent conductive material (TCO), such as ITO or IZO that can transmit light, or a semi-transmissive conductive material, such as magnesium (Mg), silver (Ag), or an alloy of Mg and Ag. When the second electrode CAT is formed of a semi-transmissive conductive material, the light emission efficiency may be improved in each of the emission areas EA1, EA2, and EA3 due to a micro-cavity effect.

The encapsulation layer TFE may be located on the light-emitting element layer EML. The encapsulation layer TFE may include at least one inorganic layer TFE1 and TFE3 to reduce or prevent permeation of oxygen or moisture into the light-emitting element layer EML. In addition, the encapsulation layer TFE may include at least one organic layer to protect the light-emitting element layer EML from foreign substances, such as dust. For example, the encapsulation layer TFE may include a first encapsulation inorganic layer TFE1, an encapsulation organic layer TFE2, and a second encapsulation inorganic layer TFE3.

The first encapsulation inorganic layer TFE1 may be located on the second electrode CAT, the encapsulation organic layer TFE2 may be located on the first encapsulation inorganic layer TFE1, and the second encapsulation inorganic layer TFE3 may be located on the encapsulation organic layer TFE2. The first encapsulation inorganic layer TFE1 and the second encapsulation inorganic layer TFE3 may be formed of multiple layers in which one or more inorganic layers of silicon nitride (SiNₓ), silicon oxynitride (SiOₓN_{y}), silicon oxide (SiOₓ), titanium oxide (TiOₓ), and aluminum oxide (AlOₓ) layers are alternately stacked. The encapsulation organic layer TFE2 may be a monomer. Alternatively, the encapsulation organic layer TFE2 may be an organic layer, such as acryl resin, epoxy resin, phenolic resin, polyamide resin, polyimide resin or the like.

An adhesive layer ADL may be a layer for bonding the encapsulation layer TFE to the optical layer OPL. The adhesive layer ADL may be a double-sided adhesive. In addition, the adhesive layer ADL may be a transparent adhesive, such as a transparent adhesive or a transparent adhesive resin.

The optical layer OPL may include a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be located on the adhesive layer ADL.

The first color filter CF1 may overlap the first emission area EA1. The first color filter CF1 may transmit light of the first color (e.g., light of a blue wavelength band). The blue wavelength band may be about 370 nm to about 460 nm. The first color filter CF1 may transmit light of the first color among light emitted from the first emission area EA1.

The second color filter CF2 may overlap the second emission area EA2. The second color filter CF2 may transmit light of the second color (e.g., light of a green wavelength band). The green wavelength band may be about 480 nm to about 560 nm. The second color filter CF2 may transmit light of the second color among light emitted from the second emission area EA2.

The third color filter CF3 may overlap the third emission area EA3. The third color filter CF3 may transmit light of the third color (e.g., light of a red wavelength band). The red wavelength band may be about 600 nm to about 750 nm. The third color filter CF3 may transmit light of the third color among light emitted from the third emission area EA3.

The plurality of lenses LNS may be located on the first color filter CF1, the second color filter CF2, and the third color filter CF3, respectively. Each of the plurality of lenses LNS may be a structure for increasing a ratio of light directed to the front of the display device 10. Each of the plurality of lenses LNS may have a cross-sectional shape that is convex in an upward direction.

The filling layer FIL may be located on the plurality of lenses LNS. The filling layer FIL may have a refractive index (e.g., predetermined refractive index) such that light travels in the third direction DR3 at an interface between the filling layer FIL and the plurality of lenses LNS. Further, the filling layer FIL may be a planarization layer. The filling layer FIL may be an organic layer, such as acrylic resin, epoxy resin, phenolic resin, polyamide resin, or polyimide resin.

The cover layer CVL may be located on the filling layer FIL. The cover layer CVL may be a glass substrate or a polymer resin. When the cover layer CVL is a glass substrate, it may be attached onto the filling layer FIL. In this case, the filling layer FIL may serve to bond the cover layer CVL. When the cover layer CVL is a glass substrate, it may serve as an encapsulation substrate. When the cover layer CVL is a polymer resin, it may be directly applied onto the filling layer FIL.

In one or more embodiments, the display part 200 may further include a polarizing plate located on the cover layer CVL. The polarizing plate may be located on one surface of the cover layer CVL. The polarizing plate may be a structure for reducing or preventing visibility degradation caused by reflection of external light. The polarizing plate may include a linear polarizing plate and a phase retardation film. For example, the phase retardation film may be a λ/4 plate (quarter-wave plate), but is not limited thereto. However, if visibility degradation caused by reflection of external light is sufficiently overcome by the first to third color filters CF1, CF2, and CF3, the polarizing plate may be omitted.

Hereinafter, various embodiments of the display device 10 will be described with reference to other drawings.

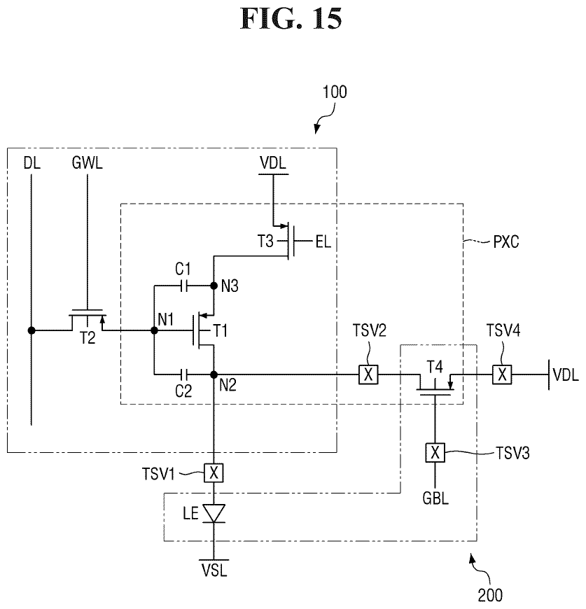

FIG. 15 is an equivalent circuit diagram of a sub-pixel of a display device according to one or more other embodiments.

Referring to FIG. 15, in the display device 10 according to one or more embodiments, the transistor of the pixel circuit PXC formed on a different single-crystal semiconductor substrate 210 is not necessarily limited to the second transistor T2. In some embodiments, in the display device 10, the fourth transistor T4 of the pixel circuit PXC may be located in the display part 200, and the first to third transistors T1, T2, and T3 and the capacitors C1 and C2 may be located in the driving part 100. In addition, the second scan line GBL and the light-emitting element LE may be located in the display part 200, and the data line DL, the first scan line GWL, the emission control line EL, and the like may be located in the driving part 100.

Because the circuit elements of the pixel circuit PXC may be dividedly located on the first single-crystal semiconductor substrate 110 of the driving part 100 and the second single-crystal semiconductor substrate 210 of the display part 200, parasitic capacitance that may be formed between adjacent circuit elements may be reduced. The circuit element located on the second single-crystal semiconductor substrate 210 may be selected as a circuit element that can more effectively reduce the parasitic capacitance. For example, in the one or more embodiments corresponding to FIG. 5, the second transistor T2 serving as a switching element is formed on the second single-crystal semiconductor substrate 210, but in the one or more embodiments corresponding to FIG. 15, the fourth transistor T4 serving as a switching element may be formed on the second single-crystal semiconductor substrate 210. Accordingly, the types of signal lines located on the second single-crystal semiconductor substrate 210 may also vary. At least one transistor constituting the pixel circuit PXC may be formed on the second single-crystal semiconductor substrate 210, and at least one signal line electrically connected to the above transistor may be located on the second single-crystal semiconductor substrate 210. If the display device 10 may reduce the high integration density suitable for the driving part 100 by including the plurality of through holes TSV1, TSV2, TSV3, and TSV4 located in the display area DAA and the non-display area NA of the display part 200, the arrangement design of the pixel circuit PXC may be modified in various ways.

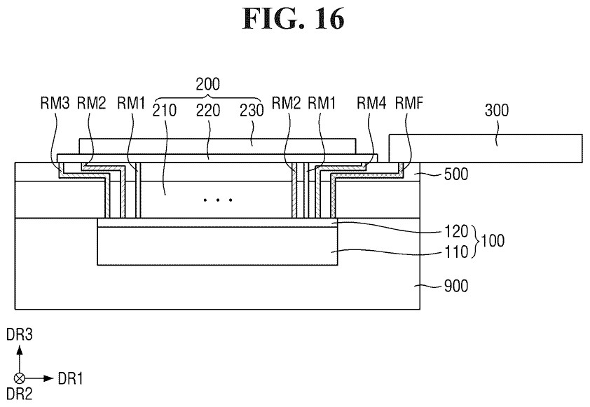

FIG. 16 is a schematic cross-sectional view of a display device according to one or more other embodiments.

Referring to FIG. 16, in the display device 10 according to one or more embodiments, the connection wiring layer 500 including the plurality of connection lines RML may be located between the second single-crystal semiconductor substrate 210 and the display element layer 230. Because the connection wiring layer 500 is located on the top surface of the second single-crystal semiconductor substrate 210 instead of the bottom surface thereof, the arrangement of the connection lines and the conductive vias of the routing lines RM1, RM2, RM3, and RM4 and the through holes may be different from that in the embodiments described above.

The connection wiring layer 500 may be located on the top surface of the second single-crystal semiconductor substrate 210. The interlayer insulating layer RINS (see FIG. 12) of the connection wiring layer 500 may be located on the top surface of the second single-crystal semiconductor substrate 210. Because a description thereof is the same as described above, a detailed description thereof will be omitted.

One ends of the routing lines RM1, RM2, RM3, RM4, and RMF located in the display part 200 may be formed across the entire second single-crystal semiconductor substrate 210, and the other ends thereof connected to the driving part 100 may be formed to correspond to the first single-crystal semiconductor substrate 110. Because the connection wiring layer 500 is located on the top surface of the second single-crystal semiconductor substrate 210, the one ends of the routing lines RM1, RM2, RM3, RM4, and RMF may be connection lines, and the other ends may be conductive vias.

In one or more embodiments, the plurality of routing lines RM1, RM2, RM3, RM4, and RMF may be arranged such that the conductive vias located in the through holes overlap the driving part 100. On the other hand, some of the connection lines of the routing lines RM1, RM2, RM3, RM4, and RMF may overlap the driving part 100 and some others thereof might not overlap the driving part 100. The connection lines of the routing lines RM1, RM2, RM3, RM4, and RMF may be located across the entire second single-crystal semiconductor substrate 210, but the ends thereof connected to the conductive vias may be concentrated in a region where the first single-crystal semiconductor substrate 110 is located.

As described above, the area of the first single-crystal semiconductor substrate 110 in plan view may be less than the area of the second single-crystal semiconductor substrate 210 in plan view, and only some of the connection lines located across the entire second single-crystal semiconductor substrate 210 may overlap the first single-crystal semiconductor substrate 110 in the thickness direction. Accordingly, the connection lines may be arranged across the entire second single-crystal semiconductor substrate 210, but the ends of the connection lines formed of a plurality of layers may overlap the first single-crystal semiconductor substrate 110 in the thickness direction, and may be connected to the plurality of through holes and the conductive vias.

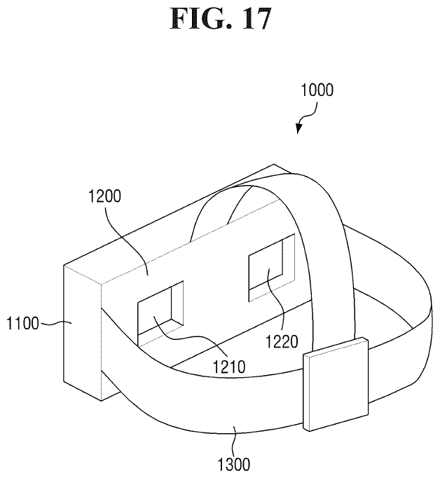

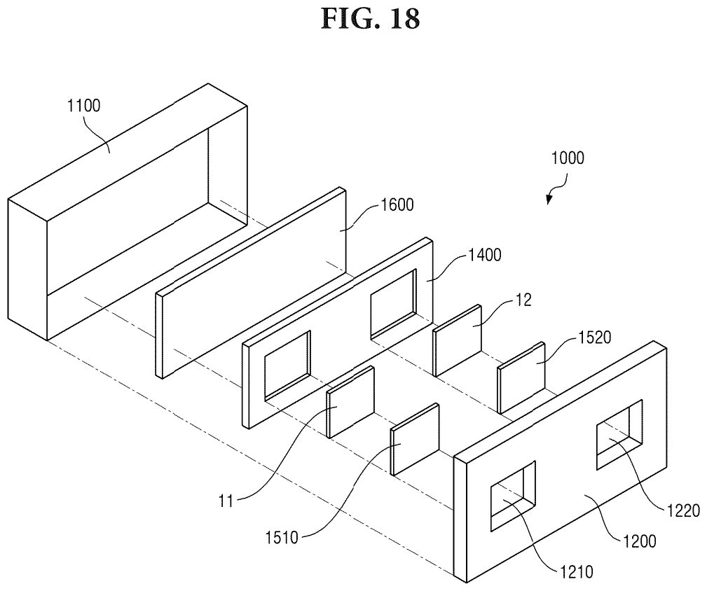

FIG. 17 is a perspective view illustrating a head mounted display device according to one or more embodiments. FIG. 18 is an exploded perspective view showing an example of the head mounted display device of FIG. 17.

Referring to FIGS. 17 and 18, a head mounted display device 1000 according to one or more embodiments includes a first display device 11, a second display device 12, a display device storage 1100, a storage cover 1200, a first eyepiece 1210, a second eyepiece 1220, a head mounted band 1300, a middle frame 1400, a first optical member 1510, a second optical member 1520, a control circuit board 1600, and a connector.

The first display device 11 provides an image to a user's left eye, and the second display device 12 provides an image to a user's right eye. Because each of the first display device 11 and the second display device 12 is substantially the same as the display device 10 described in conjunction with FIG. 1, the description of the first display device 11 and the second display device 12 will be omitted.

The first optical member 1510 may be located between the first display device 11 and the first eyepiece 1210. The second optical member 1520 may be located between the second display device 12 and the second eyepiece 1220. Each of the first optical member 1510 and the second optical member 1520 may include at least one convex lens.

The middle frame 1400 may be located between the first display device 11 and the control circuit board 1600 and between the second display device 12 and the control circuit board 1600. The middle frame 1400 serves to support and fix the first display device 11, the second display device 12, and the control circuit board 1600.

The control circuit board 1600 may be located between the middle frame 1400 and the display device storage 1100. The control circuit board 1600 may be connected to the first display device 11 and the second display device 12 through the connector. The control circuit board 1600 may convert an image source inputted from the outside into the digital video data DATA, and may transmit the digital video data DATA to the first display device 11 and the second display device 12 through the connector.

The control circuit board 1600 may transmit the digital video data DATA corresponding to a left-eye image optimized for the user's left eye to the first display device 11, and may transmit the digital video data DATA corresponding to a right-eye image optimized for the user's right eye to the second display device 12. Alternatively, the control circuit board 1600 may transmit the same digital video data DATA to the first display device 11 and the second display device 12.

The display device storage 1100 serves to accommodate the first display device 11, the second display device 12, the middle frame 1400, the first optical member 1510, the second optical member 1520, the control circuit board 1600, and the connector. The storage cover 1200 covers one open surface of the display device storage 1100. The storage cover 1200 may include the first eyepiece 1210 at which the user's left eye is located and the second eyepiece 1220 at which the user's right eye is located. It is illustrated in the drawing that the first eyepiece 1210 and the second eyepiece 1220 are located separately, but the present disclosure is not limited thereto. The first eyepiece 1210 and the second eyepiece 1220 may be combined into one.

The first eyepiece 1210 may be aligned with the first display device 11 and the first optical member 1510, and the second eyepiece 1220 may be aligned with the second display device 12 and the second optical member 1520. Accordingly, the user may view the image of the first display device 11 magnified as a virtual image by the first optical member 1510 through the first eyepiece 1210, and may view the image of the second display device 12 magnified as a virtual image by the second optical member 1520 through the second eyepiece 1220.

The head mounted band 1300 serves to secure the display device storage 1100 to the user's head such that the first eyepiece 1210 and the second eyepiece 1220 of the storage cover 1200 remain located on the user's left and right eyes, respectively. When the display device storage 1200 is implemented to be lightweight and compact, the head mounted display device 1000 may be provided with, as shown in FIG. 18, an eyeglass frame instead of the head mounted band 1300.

In addition, the head mounted display device 1000 may further include a battery for supplying power, an external memory slot for accommodating an external memory, and an external connection port and wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

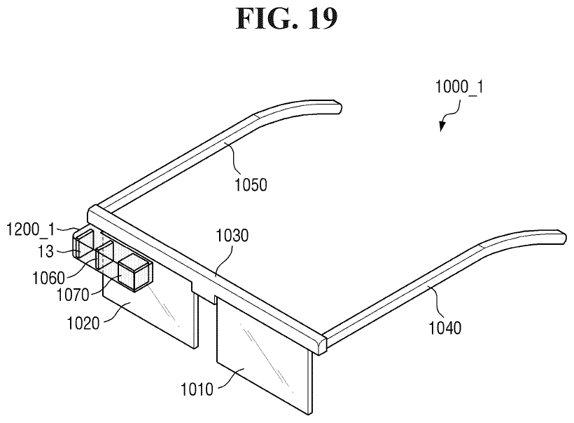

FIG. 19 is a perspective view illustrating a head mounted display device according to one or more embodiments.

Referring to FIG. 19, a head mounted display device 1000_1 according to one or more embodiments may be an eyeglasses-type display device in which a display device storage 1200_1 is implemented in a lightweight and compact manner. The head mounted display device 1000_1 according to one or more embodiments may include a display device 13, a left eye lens 1010, a right eye lens 1020, a support frame 1030, temples 1040 and 1050, an optical member 1060, an optical path conversion member 1070, and the display device storage 1200_1.

The display device storage 1200_1 may include the display device 13, the optical member 1060, and the optical path conversion member 1070. An image displayed on the display device 13 may be magnified by the optical member 1060, and the optical path may be changed by the optical path conversion member 1070 to provide the image to the user's right eye through the right eye lens 1020. As a result, the user may view an augmented reality image, through the right eye, in which a virtual image displayed on the display device 13 and a real image seen through the right eye lens 1020 are combined.

It is illustrated in the drawing that the display device storage 1200_1 is located at the right end of the support frame 1030, but the present disclosure is not limited thereto. For example, the display device storage 1200_1 may be located on the left end of the support frame 1030, and in this case, the image of the display device 13 may be provided to the user's left eye. Alternatively, the display device storage 1200_1 may be located on both the left and right ends of the support frame 1030, and in this case, the user may view the image displayed on the display device 13 through both the left and right eyes.

In concluding the detailed description, those skilled in the art will appreciate that many variations and modifications can be made to the embodiments without substantially departing from the aspects of the present disclosure. Therefore, the disclosed embodiments of the present disclosure are used in a generic and descriptive sense only and not for purposes of limitation.

1 what is claimed is:

1. A display device comprising:
a first single-crystal semiconductor substrate;
first transistors above the first single-crystal semiconductor substrate; and
a second single-crystal semiconductor substrate above the first single-crystal semiconductor substrate, having an area that is greater than an area of the first single-crystal semiconductor substrate in plan view, and comprising a display area in which light-emitting elements are located, and a non-display area around the display area in plan view,
wherein the second single-crystal semiconductor substrate defines first through holes defined in the display area and having a first conductive via electrically connected to the light-emitting element, second through holes defined in the display area and having a second conductive via electrically connected to the first transistor, and third through holes defined in the non-display area and having a third conductive via therein.

2. The display device of claim 1, further comprising:
a pixel circuit portion above the first single-crystal semiconductor substrate, and comprising some of the first transistors;
a signal driver above the first single-crystal semiconductor substrate, and comprising others of the first transistors; and
second transistors above the second single-crystal semiconductor substrate.

3. The display device of claim 2, wherein one of the light-emitting elements is electrically connected to one of the first transistor of the pixel circuit portion through the first conductive via, and
wherein one of the second transistors is electrically connected to the one of the first transistors of the pixel circuit portion through the second conductive via.

4. The display device of claim 2, further comprising signal lines located across the display area and the non-display area on the second single-crystal semiconductor substrate, and connected to the third conductive via in the non-display area.

5. The display device of claim 4, wherein the signal lines are electrically connected to the second transistors in the display area, and are electrically connected to the signal driver through the third conductive via.

6. The display device of claim 2, wherein a minimum line width of the first transistors is less than a minimum line width of the second transistors.

7. The display device of claim 1, wherein a number of the first through holes is equal to a number of the second through holes.

8. The display device of claim 1, wherein a number of the first through holes and a second through holes is greater than a number of the third through holes.

9. The display device of claim 1, wherein the first through holes overlap the light-emitting elements in a thickness direction.

10. The display device of claim 1, wherein some of the first through holes or the second through holes do not overlap the first single-crystal semiconductor substrate.

11. The display device of claim 1, wherein the third through holes do not overlap the first single-crystal semiconductor substrate.

12. The display device of claim 1, further comprising a connection wiring layer comprising connection lines electrically connected to one of the first conductive via, the second conductive via, or the third conductive via between the first single-crystal semiconductor substrate and a light-emitting element layer comprising the light-emitting elements.

13. The display device of claim 12, wherein the connection wiring layer is between the first single-crystal semiconductor substrate and the second single-crystal semiconductor substrate.

14. The display device of claim 12, wherein the connection wiring layer is between the second single-crystal semiconductor substrate and the light-emitting element layer.

15. The display device of claim 1, further comprising a passivation layer surrounding the first single-crystal semiconductor substrate, and partially in contact with the second single-crystal semiconductor substrate.

16. A display device comprising:
a first single-crystal semiconductor substrate
first transistors above the first single-crystal semiconductor substrate;
a second single-crystal semiconductor substrate above the first single-crystal semiconductor substrate;
second transistors above the second single-crystal semiconductor substrate;
at least one signal line electrically connected to the second transistor;
a light-emitting element layer above the second single-crystal semiconductor substrate, and comprising light-emitting elements; and
a connection wiring layer between the light-emitting element layer and the first single-crystal semiconductor substrate, and comprising:
a first connection line connected to a first conductive via in a first through hole penetrating the second single-crystal semiconductor substrate, and electrically connected to one of the second transistors and one of the first transistors; and
a second connection line connected to a second conductive via in a second through hole penetrating the second single-crystal semiconductor substrate, and electrically connected to any one of the signal lines.

17. The display device of claim 16, wherein the connection wiring layer further comprises a third connection line connected to a third conductive via in a third through hole penetrating the second single-crystal semiconductor substrate, and
wherein the third connection line is electrically connected to one of the light-emitting elements and one of the first transistors.

18. The display device of claim 16, wherein the signal line is electrically connected one of the first transistors above the first single-crystal semiconductor substrate through the second conductive via and the second connection line.

19. The display device of claim 16, wherein an area of the first single-crystal semiconductor substrate in plan view is less than an area of the second single-crystal semiconductor substrate in plan view.

20. A head mounted display device comprising:
a frame mounted on a user's body and corresponding to left and right eyes;
display devices in the frame; and
lenses above the display devices,
wherein the display device comprises:
a first single-crystal semiconductor substrate;
first transistors above the first single-crystal semiconductor substrate;
a second single-crystal semiconductor substrate above the first single-crystal semiconductor substrate;
second transistors above the second single-crystal semiconductor;
at least one signal line electrically connected to the second transistor;
a light-emitting element layer above the second single-crystal semiconductor substrate, and comprising light-emitting elements; and
a connection wiring layer between the light-emitting element layer and the first single-crystal semiconductor substrate, and comprising:
a first connection line connected to a first conductive via in a first through hole penetrating the second single-crystal semiconductor substrate, and electrically connected to the second transistor and the first transistor; and
a second connection line connected to a second conductive via in a second through hole penetrating the second single-crystal semiconductor substrate, and electrically connected to any one of the signal lines.
